(19) United States
(12) Patent Application Publication
(10) Pub. No.: US 2023/0215825 A1
(43) Pub. Date: Jul. 6, 2023

(54) SEMICONDUCTOR ELEMENT AND SEMICONDUCTOR DEVICE

(71) Applicant: ROHM CO., LTD., Kyoto (JP)

(72) Inventors: Reona TAKEOKA, Kyoto (JP); Toshiyuki KANAYA, Kyoto (JP); Hideshi YOSHIMOTO, Kyoto (JP)

(73) Assignee: ROHM CO., LTD., Kyoto (JP)

(21) Appl. No.: 18/008,886

(22) PCT Filed: May 25, 2021
(86) PCT No.: PCT/JP2021/019770

§ 371 Date: Dec. 7, 2022

(30) Foreign Application Priority Data
Jun. 8, 2020 (JP) 2020-099390

(51) Int. Cl. H01L 23/00

(52) U.S. Cl. CPC H01L 24/05; H01L 24/13; H01L 2224/0401; H01L 2224/05012; H01L 2224/05083; H01L 2224/05147; H01L 2224/05155; H01L 2224/05164; H01L 2224/10126; H01L 2224/13084; H01L 2224/13147; H01L 2224/13155; H01L 2924/35121

(57) ABSTRACT

A semiconductor element includes first/second electrodes on an element obverse surface, an insulating layer on the element obverse surface, and first/second electrode terminals in contact with the first/second electrodes, respectively. The insulating layer includes first/second openings, and first/second overlapping portions adjoining the first/second openings, respectively. The first/second openings expose the first/second electrodes, respectively. The first/second overlapping portions overlap with the first/second electrodes, respectively, as viewed in a thickness direction. The first/second electrode terminals are in contact with the first/second electrodes, respectively, through the first/second openings, while also overlapping with the first/second overlapping portions as viewed in the thickness direction. The first electrode terminals are in a region with a high arrangement density of electrode terminals, whereas the second electrode terminals are in a region with a low arrangement density of electrode terminals. Each first overlapping portion has a greater dimension in the thickness direction than each second overlapping portion.

### TECHNICAL FIELD

The present disclosure relates to semiconductor elements and semiconductor devices.

### BACKGROUND ART

Conventionally, a semiconductor device fabricated using flip-chip bonding of a semiconductor element onto a plurality of leads has been proposed. For fabricating such a semiconductor device, electrode terminals are formed by electroplating on the electrodes disposed on the obverse surface of the semiconductor element and connected to the leads. The arrangement of electrode terminals is not necessarily even across the obverse surface and may be locally concentrated. For instance, the obverse surface may include a region in which electrode terminals are densely arranged and a region in which electrode terminals are sparsely arranged. In electroplating for forming such electrode terminals, the density of applied electric current varies between a region where densely arranged electrode terminals are formed and a region where of sparsely electrode terminals are formed. This results in non-uniform height of the electrode terminals. Specifically, in the sparse region, the applied current tends to concentrate and thus the current density tends to be high. Consequently, higher electrode terminals are formed in the sparse region than in the dense region. Such variations in the height of the electrode terminals degrade the coplanarity (the evenness of the mounting surfaces of the electrode terminals). As a result, lower electrode terminals may not be properly bonded to the leads and cause connection failures.

In an attempt to reduce variations in the height of electrode terminals, a manufacturing method disclosed in Patent Document 1 for flip-chip bonding of a semiconductor element includes forming dummy electrode terminals in a region where electrode terminals to be formed are sparse and later removing the dummy electrode terminals. This method, however, is complicated by the need to form a foundation layer including a removable part, to form dummy electrode terminals and to later remove the dummy electrode terminals. Moreover, the material used for the dummy electrode terminals needs to be wasted.

### PRIOR ART DOCUMENT

### Patent Document

Patent Document 1: JP-A-2016-189404

### SUMMARY OF THE INVENTION

### Problem to be Solved by the Invention

In view of the circumstances described above, the present disclosure may aim to provide a semiconductor element that includes electrode terminals whose height variations are reduced in a simple manner.

### Means to Solve the Problem

In accordance with an aspect of the present disclosure, there is provided a semiconductor element including: an element obverse surface and an element reverse surface facing away from each other in a thickness direction; a plurality of electrodes disposed on the element obverse surface; an insulating layer disposed on the element obverse surface; and a plurality of electrode terminals each being held in contact with one of the plurality of electrodes and partly overlapping with the insulating layer as viewed in the thickness direction. The insulating layer includes a plurality of openings and a plurality of overlapping portions adjoining the plurality of openings, respectively, where the plurality of openings expose the plurality of electrodes, respectively, and the plurality of overlapping portions overlap with the plurality of electrodes, respectively, as viewed in the thickness direction.

The plurality of electrode terminals are in contact with the plurality of electrodes, respectively, through the plurality of openings, while also overlapping with the plurality of overlapping portions, respectively, as viewed in the thickness direction. The plurality of electrode terminals include a plurality of first electrode terminals that are densely arranged as viewed in the thickness direction and a plurality of second electrode terminals that are sparsely arranged as viewed in the thickness direction. Each of the overlapping portions that overlaps with one of the plurality of first electrode terminals has a greater dimension in the thickness direction than each of the overlapping portions that overlaps with one of the plurality of second electrode terminals.

### Advantages of Invention

According to the present disclosure, a thicker overlapping portion is provided for each of the densely arranged electrode terminals (the first electrode terminals), and a thinner overlapping portion is provided for each of the sparsely arranged electrode terminals (the second electrode terminals). Thus, although the second electrode terminals have a greater height from the insulating layer than the first electrode terminals due to the electric current concentration, the variations in the height of the electrode terminals (the height from the relevant electrodes) are compensated for.

Other features and advantages of the present disclosure will be more apparent from the detailed description given below with reference to the accompanying drawings.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1, with a sealing resin shown as transparent.

FIG. 3 is a plan view of the semiconductor device shown in FIG. 1, with a semiconductor element also shown as transparent.

FIG. 4 is a bottom view of the semiconductor device shown in FIG. 1.

FIG. 5 is a plan view of a semiconductor element according to the first embodiment of the present disclosure.

FIG. 6 is a front view of the semiconductor device shown in FIG. 1.

FIG. 7 is a rear view of the semiconductor device shown in FIG. 1.

FIG. 8 is a right-side view of the semiconductor device shown in FIG. 1.

FIG. 9 is a left-side view of the semiconductor device shown in FIG. 1.

FIG. 10 is a sectional view taken along line X-X of FIG. 3.

FIG. 11 is a sectional view taken along line XI-XI of FIG. 3.

FIG. 12 is a sectional view taken along line XII-XII of FIG. 3.

FIG. 13 is a sectional view taken along line XIII-XIII of FIG. 3.

FIG. 14 is an enlarged view showing a portion of FIG. 10.

FIG. 15 is an enlarged sectional view of a portion taken along line XV-XV of FIG. 14.

FIG. 16 is an enlarged view showing a portion of FIG. 10.

FIG. 17 is a view illustrating dimension differences between the electrode terminals formed at different arrangement densities.

FIG. 18 is a schematic sectional view of the semiconductor device where variations in the height of the electrode terminals are reduced but not completely.

FIG. 19 is a plan view of a semiconductor device according to a second embodiment of the present disclosure, with a sealing resin and a semiconductor element shown as transparent.

FIG. 20 is a plan view of a semiconductor device according to a third embodiment of the present disclosure, with a sealing resin shown as transparent.

FIG. 21 is a sectional view taken along line XXI-XXI of FIG. 20.

FIG. 22 is a plan view of a semiconductor device according to a fourth embodiment of the present disclosure, with a sealing resin shown as transparent.

FIG. 23 is a sectional view taken along line XXIII-XXIII of FIG. 22.

FIG. 24 is a sectional view taken along line XXIV-XXIV of FIG. 22.

FIG. 25 is a fragmentary plan view of a semiconductor device according to a fifth embodiment of the present disclosure, with a sealing resin shown as transparent.

FIG. 26 is a fragmentary plan view of a semiconductor device according to a sixth embodiment of the present disclosure, with a sealing resin shown as transparent.

### MODE FOR CARRYING OUT THE INVENTION

The following describes preferred embodiments of the present disclosure with reference to the accompanying drawings.

In the present disclosure, the phrases “an object A is formed with an object B” and “an object A is formed on an object B” include, unless otherwise specified, “an object A is formed directly on an object B” and “an object A is formed above an object B with another object interposed between the object A and the object B”. Similarly, the phrases “an object A is disposed over an object B” and “an object A is disposed on an object B” include, unless otherwise specified, “an object A is disposed directly on an object B” and “an object A is disposed above an object B with another object interposed between the object A and the object B”. Similarly, the phrase “an object A is located on an object B” includes, unless otherwise specified, “an object A is located on and in contact with the object B” and “an object A is located above an object B with another object interposed between the object A and the object B”. Also, the phrase “an object A overlaps with an object B as viewed in a certain direction” includes, unless otherwise specified, “the object A overlaps with the entire object B” and “the object A overlaps with a portion of the object B”.

### First Embodiment

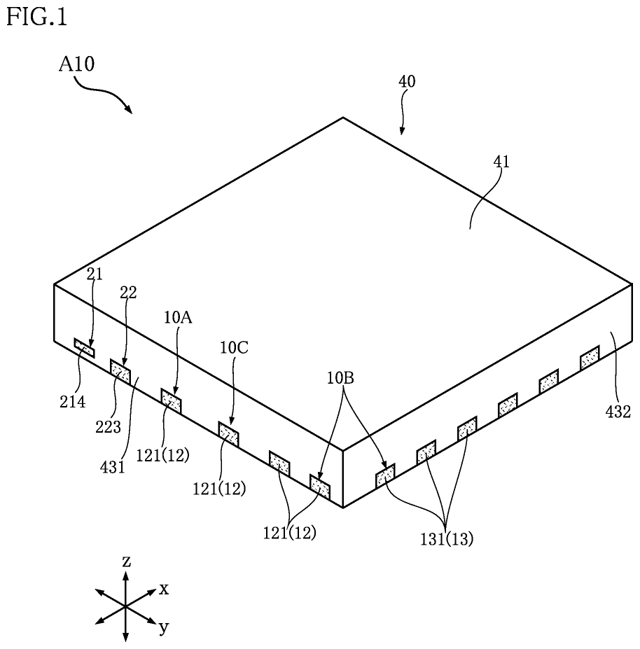

FIGS. 1 to 16 show an example of a semiconductor device according to the present disclosure. A semiconductor device A10 of a first embodiment includes a plurality of first leads 10A, 10B and 10C, a plurality of second leads 21, a pair of third leads 22, a semiconductor element 30 and a sealing resin 40. The package type of the semiconductor device A10 is not particularly limited, and this embodiment employs the QFN (Quad Flat Non-leaded package) as shown in FIG. 1. The usage and function of semiconductor device A10 are not limited either. As to the usage, the semiconductor device A10 may be used for an electronic device, a general industrial device, a vehicle-mounted device, etc. As to the functionality, the semiconductor device A10 may be a DC/DC converter, an AC/DC converter, etc. The semiconductor device A10 of this embodiment is configured as a vehicle-mount DC/DC converter.

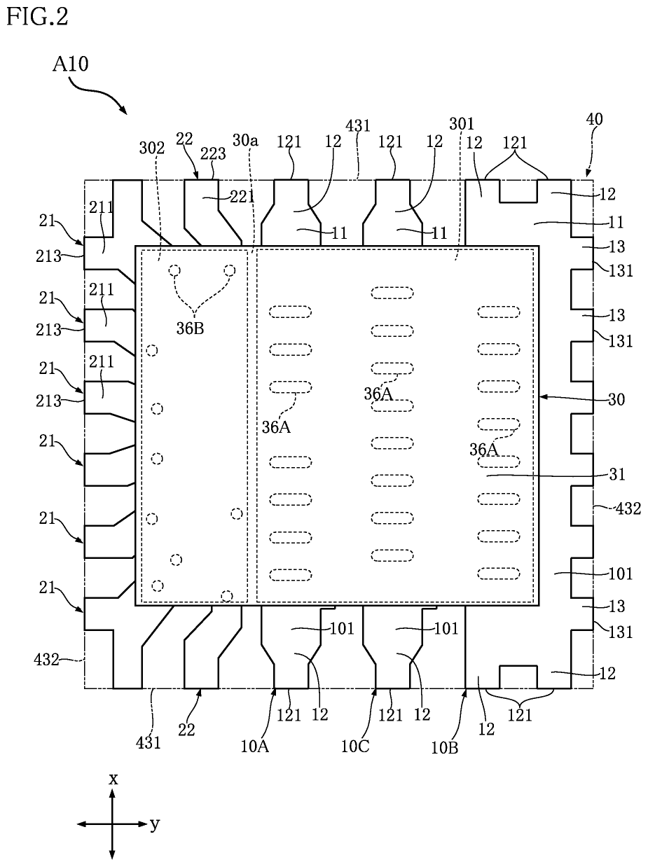

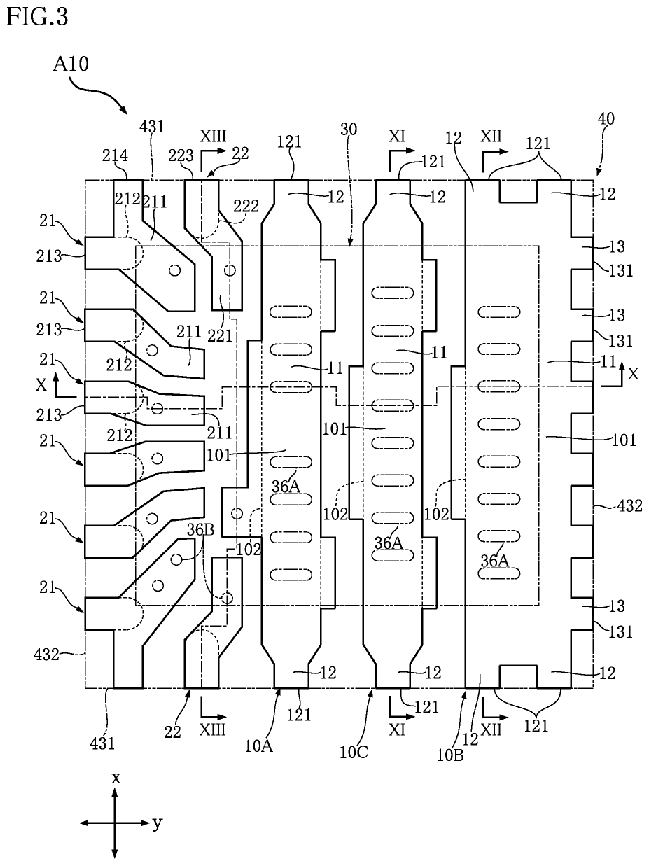

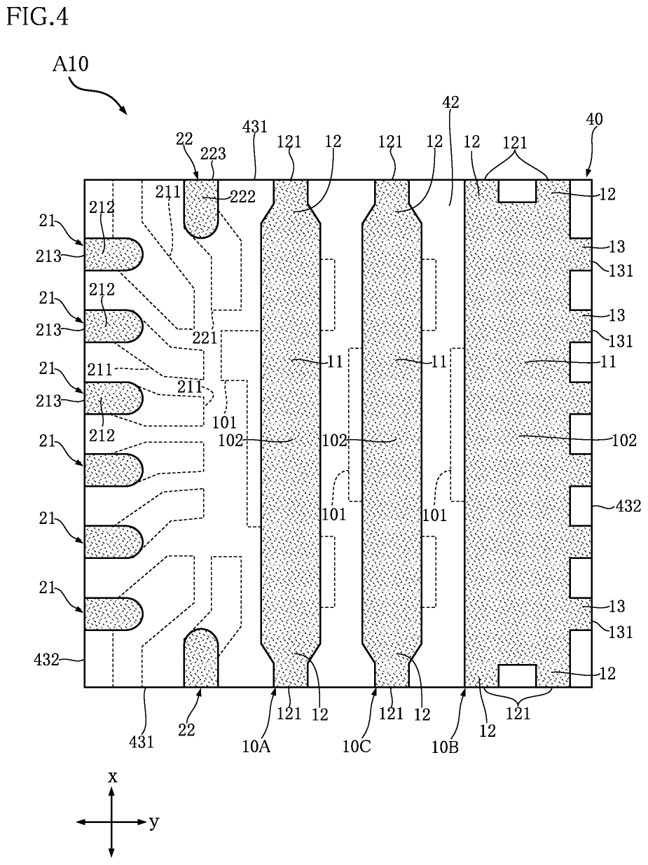

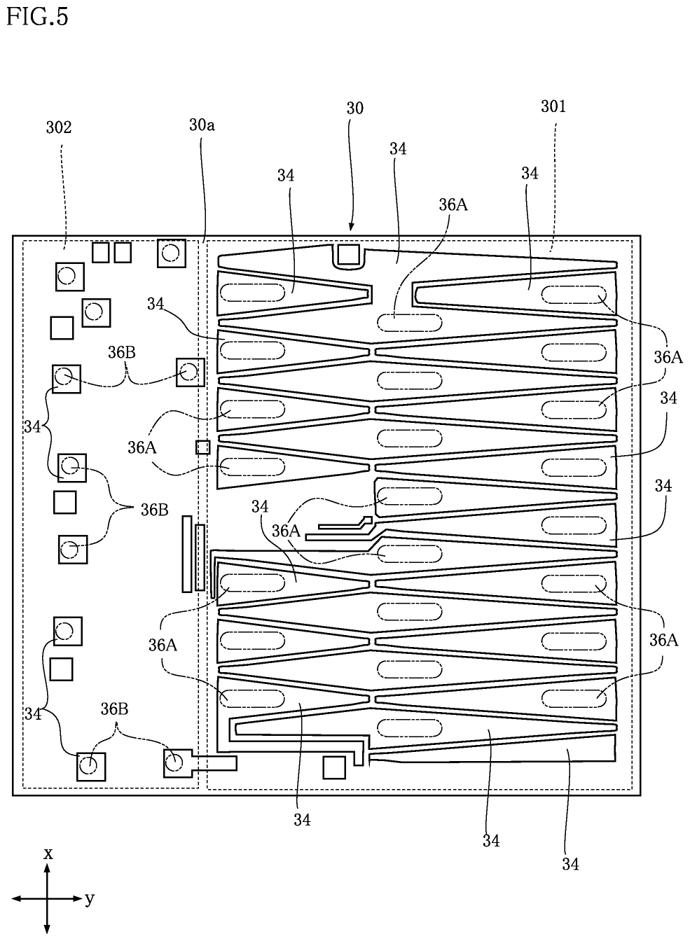

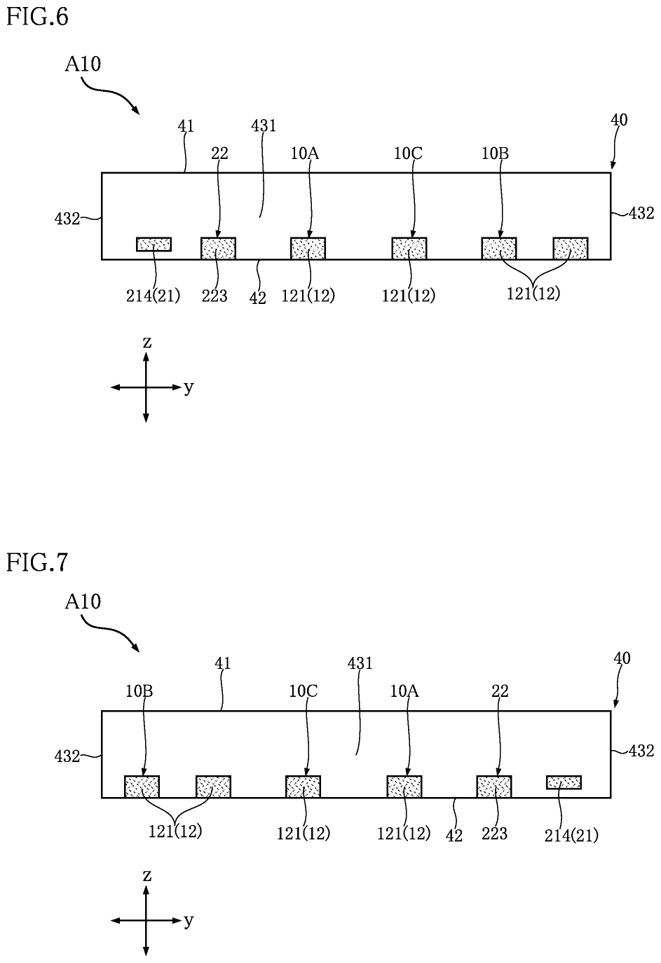

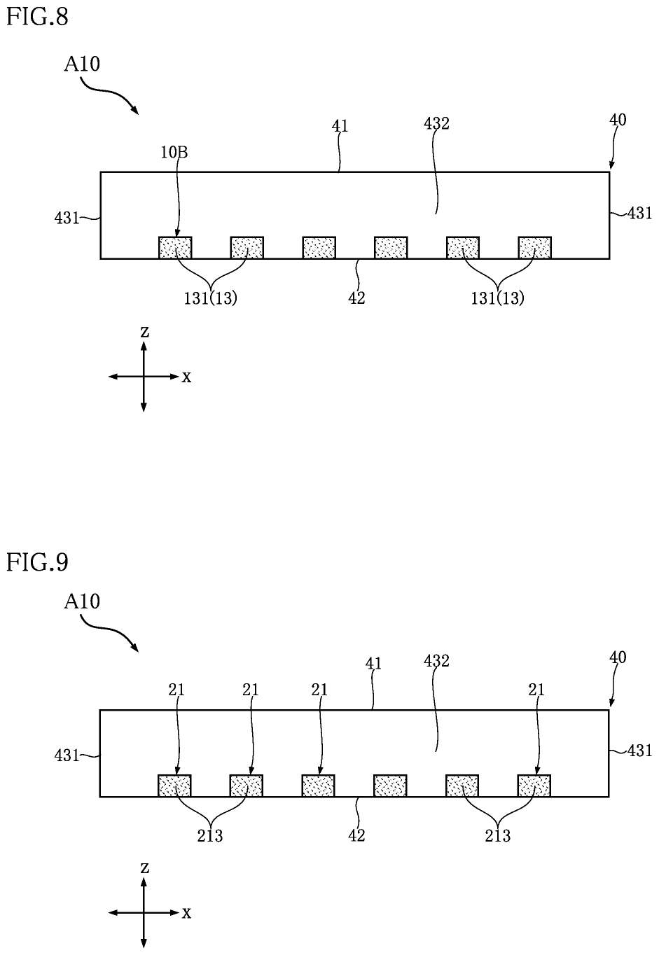

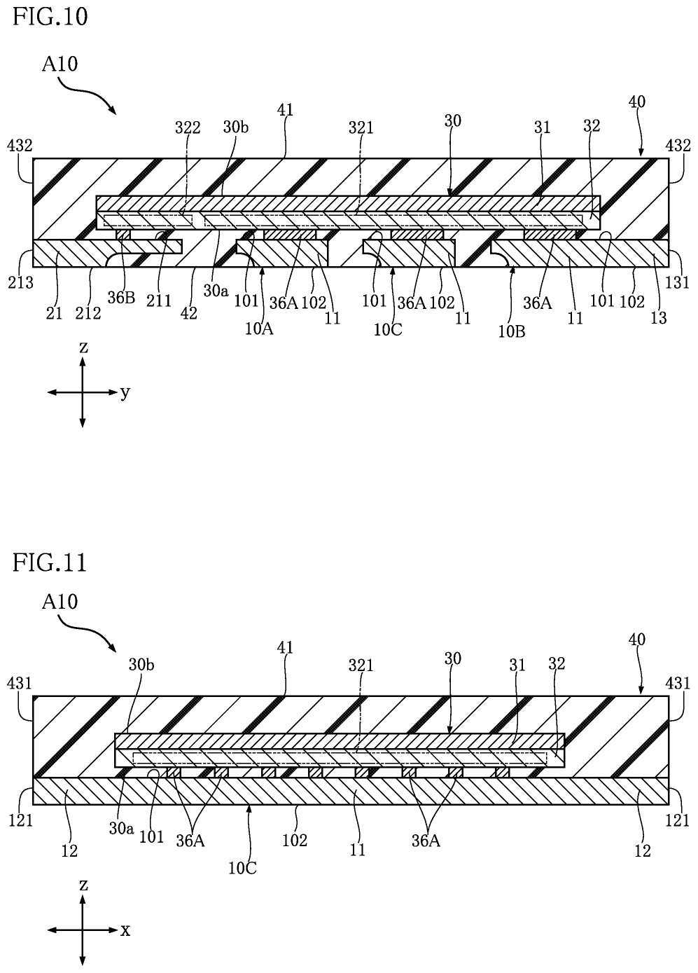

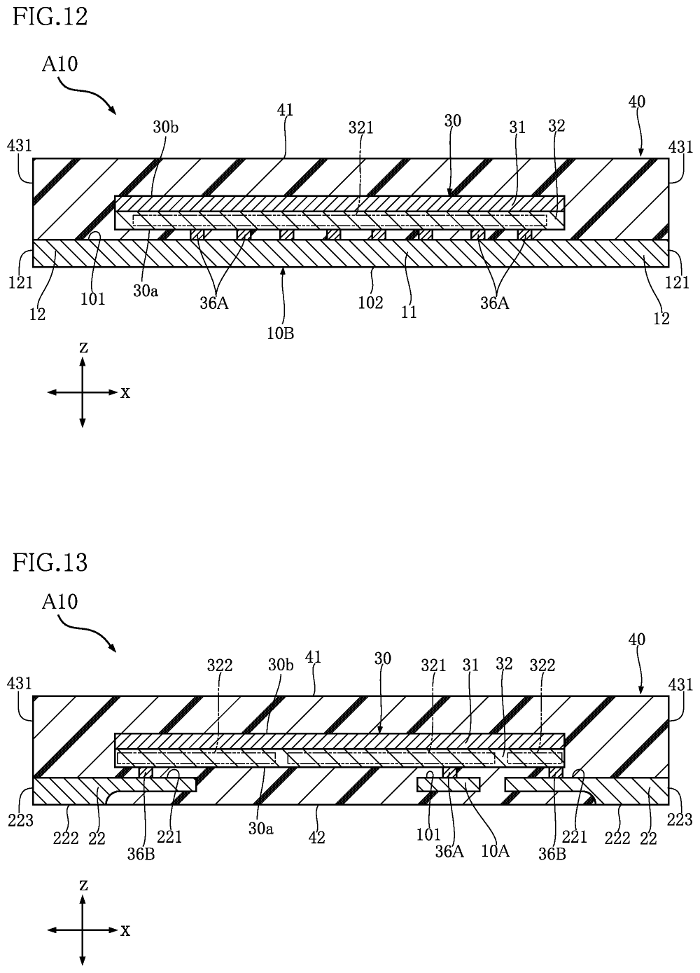

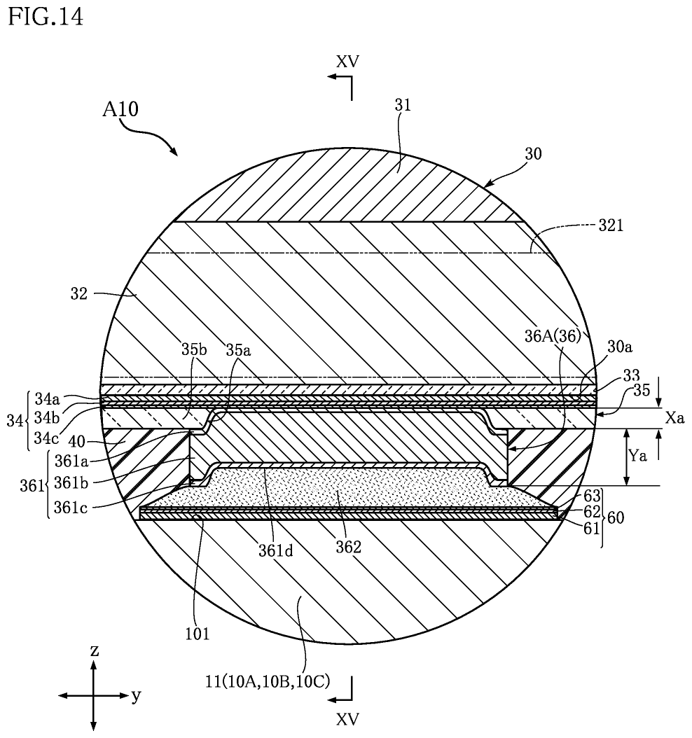

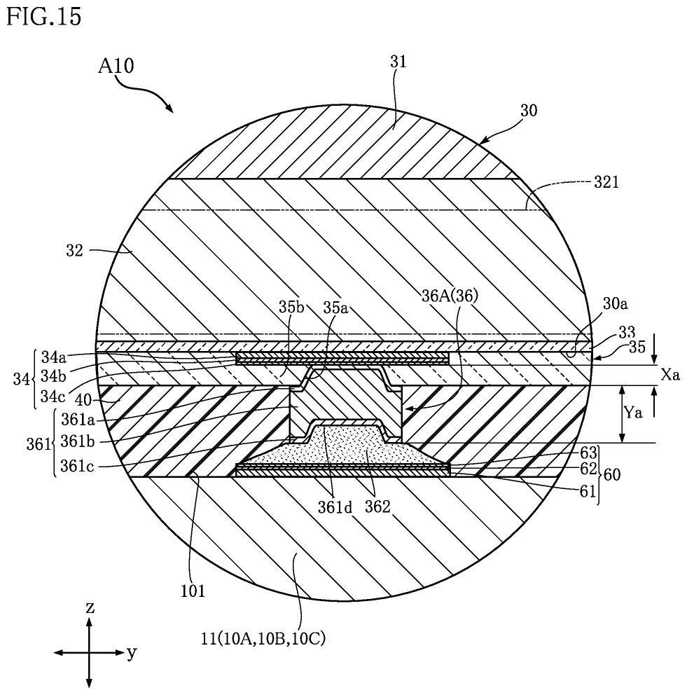

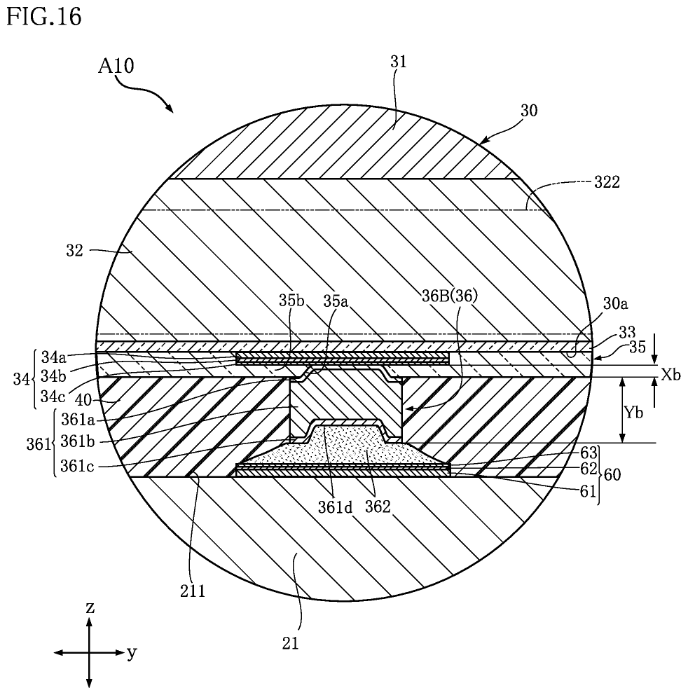

FIG. 1 is a perspective view of the semiconductor device A10. FIG. 2 is a plan view of the semiconductor device A10. For convenience, FIG. 2 shows the sealing resin 40 as transparent, and the outline of the sealing resin 40 is shown in phantom (chain double-dashed line). FIG. 3 is a plan view of the semiconductor device A10. For convenience, FIG. 3 shows the sealing resin 40 and the semiconductor element 30 as transparent, and the outlines of the sealing resin 40 and the semiconductor element 30 are shown in phantom (chain double-dashed line). FIG. 4 is a bottom view of the semiconductor device A10. FIG. 5 is a plan view of the semiconductor element 30. In FIG. 5, the insulating layer 35 and a plurality of electrode terminals 36 are shown as transparent, and the outlines of the electrode terminal 36 are shown in phantom (chain double-dashed lines). FIG. 6 is a front view of the semiconductor device A10. FIG. 7 is a rear view of the semiconductor device A10. FIG. 8 is a right-side view of the semiconductor device A10. FIG. 9 is a left-side view of the semiconductor device A10. FIG. 10 is a sectional view taken along line X-X of FIG. 3. FIG. 11 is a sectional view taken along line XI-XI of FIG. 3. FIG. 12 is a sectional view taken along line XII-XII of FIG. 3. FIG. 13 is a sectional view taken along line XIII-XIII of FIG. 3. FIG. 14 is an enlarged view showing a portion (around an electrode terminal 36A described later) of FIG. 10. FIG. 15 is an enlarged sectional view of a portion taken along line XV-XV of FIG. 14. FIG. 16 is an enlarged view showing a portion (around an electrode terminal 36B described later) of FIG. 10.

As shown in FIG. 1, the semiconductor device A10 generally has the shape of a plate. Specifically, the semiconductor device A10 has the shape of a hexahedron with a relatively low height (a small z-direction dimension) and has the shape of a rectangle as viewed in the thickness direction (plan view). For convenience, the thickness direction of the semiconductor device A10 is defined as the z direction, and a direction perpendicular to the z direction along one edge of the semiconductor device A10 is defined as the x direction (the vertical direction in FIGS. 2 to 4), and the direction perpendicular to the z and x directions is defined as the y direction (the horizontal direction in FIGS. 2 to 4). The shape and the dimensions of the semiconductor device A10 are not particularly limited.

As shown in FIG. 2, the first leads 10A, 10B and 10C, the second leads 21 and the third leads 22 support the semiconductor element 30 and serve as terminals for connecting the semiconductor device A10 to a wiring board. As shown in FIGS. 10 to 13, the first leads 10A, 10B and 10C, the second leads 21 and the third leads 22 have portions covered with the sealing resin 40 and portions not covered with the sealing resin 40. In FIGS. 1 and 4 to 9, the exposed portions of the first leads 10A, 10B and 10C, the second leads 21 and the third leads 22 are shaded with dots.

The first leads 10A, 10B and 10C, the second leads 21 and the third leads 22 may be formed from a metal plate by etching. In another example, the first leads 10A, 10B and 10C, the second leads 21 and the third leads 22 may be formed from a metal plate by punching and/or bending. The first leads 10A, 10B and 10C, the second leads 21 and the third leads 22 are spaced apart from each other. The first leads 10A, 10B and 10C, the second leads 21 and the third leads 22 may be made of, but not limited to, Cu or a Cu alloy.

As shown in FIGS. 3 and 4, each of the first leads 10A, 10B and 10C is shaped like a strip extending in the x direction as viewed in the z direction. Each of the first leads 10A, 10B and 10C has a first obverse surface 101 and a first reverse surface 102 facing away from each other in the z direction. The first obverse surface 101 faces in a first sense of the z direction and is opposed to the semiconductor element 30. The first obverse surface 101 is covered with the sealing resin 40. The first reverse surface 102 faces in a second sense of the z direction. The first reverse surface 102 is exposed from the sealing resin 40. The first leads 10A, 10B and 10C support the semiconductor element 30 on their first obverse surfaces 101. In the example shown in FIGS. 3 and 4, the first obverse surface 101 of each of the first leads 10A, 10B and 10C has a larger area than the relevant first reverse surface 102. Each of the first leads 10A, 10B and 10C has at least one portion (anchoring portion) where the first obverse surface 101 does not overlap with the first reverse surface 102 as viewed in the z direction. Such an anchoring portion may be formed by applying half etching from the first reverse surface 102. Each of the first leads 10A, 10B and 10C includes one or more anchoring portions, producing the effect of preventing the lead from peeling off from the bottom surface 42 of the sealing resin 40 (hereinafter “anchoring effect”).

The first leads 10A and 10B receive direct-current power (voltage) to be converted by the semiconductor device A10. In the present embodiment, the first lead 10A is a positive electrode (P terminal). The first lead 10B is a negative electrode (negative terminal). The first lead 10C outputs alternating-current power (voltage) converted by a later-described switching circuit 321 of the semiconductor element 30. As shown in FIG. 3, the first leads 10A, 10B and 10C are arranged in the order of the first lead 10A, the first lead 10C and the first leads 10B from one side in a first sense of the y direction to the other side in a second sense of the y direction. The first lead 10A is located between the plurality of second leads 21 and the first lead 10C in the y direction. The first lead 10C is located between the first lead 10A and the first lead 10C in the y direction.

As shown in FIGS. 3 and 4, the first leads 10A and 10C have a main section 11 and a pair of side sections 12. The main section 11 extends in the x direction. The pair of side sections 12 are connected to the opposite ends of the main section 11 in the x direction and are narrower in the y direction than the main section 11. Each side section 12 has a first end surface 121. As shown in FIG. 11, the first end surface 121 is connected to the first obverse surface 101 and the first reverse surface 102 and faces in the x direction. The first end surface 121 is exposed from the sealing resin 40.

As shown in FIGS. 3 and 4, the first lead 10B includes a main section 11, four side sections 12 and a plurality of projections 13. The main section 11 extends in the x direction. Two of the side sections 12 are connected to one end of the main section 11 in the x direction. The other two side sections 12 are connected to the other end of the main section 11 in the x direction. Each of the four side sections 12 has a first end surface 121. As shown in FIG. 12, the first end surface 121 is connected to the first obverse surface 101 and the first reverse surface 102 and faces in the x direction. The first end surface 121 is exposed from the sealing resin 40. Each projection 13 protrudes from the main section 11 in the second sense of the y direction. The spaces between adjacent projections 13 are filled with the sealing resin 40. Each projection 13 has a sub-end surface 131. As shown in FIG. 10, each sub-end surface 131 is connected to the first obverse surface 101 and the first reverse surface 102 and faces in the second sense of the y direction. The sub-end surfaces 131 are exposed from the sealing resin 40. As shown in FIG. 8, the sub-end surfaces 131 are arranged at predetermined spaced intervals in the x direction. Note, however, that the first leads 10A, 10B and 10C are not limited to such a shape having the main section 11 and the side sections 12.

Each of the first leads 10A, 10B and 10C may have Sn plating on the first reverse surface 102, the first end surfaces 121 and the sub-end surfaces 131 that are exposed from the sealing resin 40. Instead of the Sn plating, a plurality of metal layers may be deposited in the order of Ni, Pd and Au.

As shown in FIG. 3, the plurality of second leads 21 are offset from the first leads 10 in the first sense of the y direction. One of the second leads 21 serves as a ground terminal of a later-described control circuit 322 of the semiconductor element 30. The other second leads 21 receive electric power (voltage) for driving the control circuit 322 or receive an electric signal to be transmitted to the control circuit 322. As shown in FIGS. 3 and 4, each second lead 21 has a second obverse surface 211, a second reverse surface 212 and a second end surface 213. The shape of each second lead 21 is not particularly limited.

Each second obverse surface 211 faces in the same direction as the first obverse surfaces 101 of the first leads 10 in the z direction and is opposed to the semiconductor element 30. The second obverse surface 211 is covered with the sealing resin 40. The semiconductor element 30 is supported on the second obverse surface 211. The second reverse surface 212 faces away from the second obverse surface 211. The second reverse surface 212 is exposed from the sealing resin 40. The second end surface 213 is connected to the second obverse surface 211 and the second reverse surface 212 and faces in the first sense of the y direction. The second end surface 213 is exposed from the sealing resin 40. As shown in FIG. 9, the second end surfaces 213 are arranged at predetermined spaced intervals in the x direction. Two of the second leads 21 are located at the opposite ends in the x direction and additionally has a fourth end surface 214. Each fourth end surface 214 faces in the x direction and is exposed from the sealing resin 40. As shown in FIGS. 3 and 4, the second obverse surface 211 of each second lead 21 has a larger area than the relevant second reverse surface 212. Each second lead 21 has a portion where the second obverse surface 211 does not overlap with the second reverse surface 212 as viewed in the z direction. Such a portion may be formed by applying half etching from the second reverse surface 212 and serves to produce the anchoring effect of preventing the second lead 21 from peeling off from the bottom surface 42 of the sealing resin 40.

Each second lead 21 may have Sn plating on the second reverse surface 212, the second end surface 213 and the fourth end surface 214 that are exposed from the sealing resin 40. Instead of the Sn plating, a plurality of metal layers may be deposited in the order of Ni, Pd and Au.

As shown in FIG. 3, the pair of third leads 22 are located between the first lead 10A and the plurality of second leads 21. The third leads 22 are spaced apart from each other in the x direction. Each third lead 22 receives an electric signal to be transmitted to the control circuit 322 formed in the semiconductor element 30. As shown in FIGS. 3 and 4, each third lead 22 has a third obverse surface 221, a third reverse surface 222, and a third end surface 223. The shape of each third lead 22 is not particularly limited.

The third obverse surface 221 faces in the same direction as the first obverse surfaces 101 of the first leads 10 in the z direction and is opposed to the semiconductor element 30. The third obverse surface 221 is covered with the sealing resin 40. The semiconductor element 30 is supported on the third obverse surface 221. The third reverse surface 222 faces away from the third obverse surface 221. The third reverse surface 222 is exposed from the sealing resin 40. The third end surface 223 is connected to the third obverse surface 221 and the third reverse surface 222 and faces in the x direction. The third end surface 223 is exposed from the sealing resin 40. The third end surface 223 of each third lead 22 is aligned with the first end surfaces 121 of the first leads 10 in the y direction. In the illustrated example, the third obverse surface 221 of each third lead 22 has a larger area than the relevant third reverse surface 222. Each third lead 22 has a portion where the third obverse surface 221 does not overlap with the third reverse surface 222 as viewed in the z direction. Such a portion may be formed by applying half etching from the third reverse surface 222 and serves to produce the anchoring effect of preventing the third lead 22 from peeling off from the bottom surface 42 of the sealing resin 40.

Each third lead 22 may have Sn plating on the third reverse surface 222 and the third end surface 223 that are exposed from the sealing resin 40. Instead of the Sn plating, a plurality of metal layers may be deposited in the order of Ni, Pd and Au.

The first leads 10A, 10B and 10C, the second leads 21 and the third leads 22 may be formed with a plurality of recesses that are recessed in the z direction from the obverse surfaces 101, 211 and 221. The recesses may be formed by applying half etching from the obverse surfaces 101, 211 and 221. With the inner surface of each recess closely receiving the sealing resin 40, the adhesion of the leads and the sealing resin 40 improves. The recesses also facilitate proper positioning of the semiconductor element 30 as viewed in the z direction (the positioning in the xy plane). The first leads 10A, 10B and 10C, the second leads 21 and the third leads 22 are not particularly limited as to the number, shape and arrangement.

As shown in FIG. 2, the semiconductor element 30 is located centrally of the semiconductor device A10 as viewed in the z direction. As shown in FIGS. 10 to 16, the semiconductor element 30 is supported on the first leads 10A, 10B and 10C, the second leads 21 and the third leads 22. The semiconductor element 30 is covered with the sealing resin 40. The semiconductor element 30 includes a semiconductor substrate 31, a semiconductor layer 32, a passivation film 33, a plurality of electrodes 34, an insulating layer 35 and a plurality of electrode terminals 36. The semiconductor element 30 is a flip-chip LSI having circuitry inside.

As shown in FIG. 2, the semiconductor element 30 is rectangular as viewed in the z direction and generally has the shape of a plate as shown in FIGS. 10 to 13. The semiconductor element 30 has an element obverse surface 30a and an element reverse surface 30b. In the z direction, the element obverse surface 30a is directed toward the first obverse surfaces 101 of the first leads 10A, 10B and 10C, the second obverse surfaces 211 of the second leads 21, and the third obverse surfaces 221 of the third leads 22. The element reverse surface 30b faces away from the element obverse surface 30a in the z direction. As indicted by the broken lines in FIG. 2, the element obverse surface 30a includes a first region 301 and a second region 302. The first region 301 of the element obverse surface 30a includes portions opposite the first obverse surfaces 101 of the first leads 10A, 10B and 10C and is offset in the second sense of the y direction (to the right in FIG. 2). The second region 302 of the element obverse surface 30a includes portions opposite the second obverse surfaces 211 of the second leads 21 and the third obverse surfaces 221 of the third lead 22 and is offset in the first sense of the y direction (to the left side in FIG. 2).

As shown in FIGS. 14 to 16, the semiconductor layer 32, the passivation film 33, the electrodes 34, the insulating layer 35 and the electrode terminals 36 are disposed below the semiconductor substrate 31 in the z direction. The semiconductor substrate 31 may be made of silicon (Si) or silicon carbide (SiC). In this embodiment, one side of the semiconductor substrate 31 forms the element reverse surface 30b.

As shown in FIGS. 10 to 13, the semiconductor layer 32 is disposed on the side of the semiconductor substrate 31 facing toward the first obverse surfaces 101 of the first leads 10 in the z direction. The semiconductor layer 32 may be made of any of a variety of types of p-type or n-type semiconductors depending on the amount of dopant. The semiconductor layer 32 is formed with the switching circuit 321 and the control circuit 322 that is electrically connected to the switching circuit 321. The switching circuit 321 may be a metal-oxide-semiconductor field-effect transistor (MOSFET) or an insulated gate bipolar transistor (IGBT), for example. In the example of the semiconductor device A10, the switching circuit 321 is divided into two regions: a high-voltage region (upper arum circuit) and a low-voltage region (lower arm circuit). Each region is formed with one n-channel MOSFET. The control circuit 322 includes a gate driver for driving the switching circuit 321 and/or a bootstrap circuit for the high-voltage region of the switching circuit 321 and operates to drive the switching circuit 321 normally. The semiconductor layer 32 is also formed with a wiring layer (not shown). The wiring layer electrically connects the switching circuit 321 and the control circuit 322.

As shown in FIGS. 14 to 16, the passivation film 33 covers the undersurface of the semiconductor layer 32. The passivation film 33 is electrically insulating. The passivation film 33 is formed by a film of silicon oxide (SiO₂) disposed in contact with the undersurface of the semiconductor layer 32 and a film of silicon nitride (Si₃N₄) formed on the silicon oxide film. In this embodiment, one side of the passivation film 33 forms the element obverse surface 30a.

As shown in FIG. 5, the electrodes 34 are disposed on the element obverse surface 30a. As viewed in the z direction, the electrodes 34 in the first region 301 may have a triangular or rhombus shape elongated in the y direction. In this embodiment, the electrodes 34 include those having the shape of an isosceles triangle with the vertex pointing in the first sense of the y directing (to the left in FIG. 5) arranged at equally spaced intervals in the x direction along the edge of the first region 301 in the second sense of the y direction (the right edge in FIG. 5). The electrodes 34 also includes those having the shape of an isosceles triangle with the vertex pointing in the second sense of the y direction arranged at equally spaced intervals in the x direction along the edge of the first region 301 in the first sense of the y direction. The isosceles triangular electrode electrodes 34 are arranged such that the vertex of one electrode 34 offset in the first sense of the y direction is opposed to the vertex of one electrode 34 offset in the second sense of the y direction. The electrodes 34 further include those having a rhombus shape, and each rhombus-shaped electrode is disposed between an isosceles triangular electrode 34 offset in the second sense of the y direction and an isosceles triangular electrode 34 offset in the first sense of the y direction. The electrodes 34 offset in the second sense of the y direction are electrically connected to the first lead 10B via the relevant electrode terminals 36. The electrodes 34 offset in the first sense of the y direction are electrically connected to the first lead 10A via the relevant electrode terminals 36. The electrodes 34 located in between are electrically connected to the first lead 10C via the relevant electrode terminals 36. The electrodes 34 in the second region 302 may have a rectangular shape as viewed in the z direction. In the second region 302, the electrodes 34 are isolated from each other. The electrodes 34 located in the second region 302 include those electrically connected to the second leads 21 and those electrically connected to the third leads 22 via the relevant electrode terminals 36. The shape and arrangement of each electrode 34 as viewed in the z direction are not particularly limited. The electrodes 34 adjacent to each other are separated by a slit (gap). The slits shown in FIG. 5 have the shape of a linear line segment in plan view. The planar shape of the slits is not limited to a linear line segment. The slits may have a wavy line shape or a zig-zag line shape in plan view.

As shown in FIGS. 14 to 16, the passivation film 33 is formed with a plurality of openings (not show) through which each electrode 34 is connected to the wiring layer formed in the semiconductor layer 32. Thus, each electrode 34 is connected to either the switching circuit 321 or the control circuit 322 also formed in the semiconductor layer 32. The electrodes 34 of this embodiment is composed of a plurality of metal layers, including a first layer 34a, a second layer 34b and a third layer 34c, stacked downward on the passivation film 33. The first layer 34a is in contact with the passivation film 33 and made of Cu. The second layer 34b is in contact with the first layer 34a and made of Ni. The third layer 34c is in contact with the second layer 34b and made of Ni. Yet, the configuration of the electrodes 34 is not limited.

As shown in FIGS. 14 to 16, the insulating layer 35 is formed on the element obverse surface 30a and covers the passivation film 33 and portions of the electrodes 34. The insulating layer 35 is electrically insulating. The insulating layer 35 of this embodiment is made of a phenolic resin. Yet, the material of the insulating layer 35 is not limited, and another insulating material such as a polyimide resin may be used. The insulating layer 35 includes a plurality of openings 35a. Each opening 35a exposes one of the electrodes 34. The insulating layer 35 also includes a plurality of overlapping portions 35b. Each overlapping portion 35b adjoins one of the openings 35a and partly overlaps with one of the electrodes 34 that is exposed through the opening 35a as viewed in the z direction. The insulating layer 35 may be formed by applying a photosensitive resin using a spin coater, followed by photolithography.

As shown in FIGS. 10 to 13, each electrode terminal 36 is disposed on or near the element obverse surface 30a in the z direction and protrudes toward a relevant first obverse surface 101, a second obverse surface 211 or a third obverse surface 221. Also, as shown in FIGS. 14 to 16, each electrode terminal 36 is in contact with an electrode 34 through an opening 35a of the insulating layer 35 and partly overlaps with an overlapping portion 35b of the insulating layer 35. Specifically, the central portion of each electrode terminal 36 as viewed in the z direction is in contact with the relevant electrode 34, and the peripheral portion overlaps with the relevant overlapping portion 35b. The electrode terminals 36 are electrically conductive.

As shown in FIGS. 14 to 16, each electrode terminal 36 includes a pillar portion 361 and a solder portion 362. The pillar portion 361 includes a seed layer 361a, a first plating layer 361b and a second plating layer 361c. The seed layer 361a is in contact with the relevant electrode 34 and the insulating layer 35 and contains Cu. The seed layer 361a may be formed by electroless plating. Yet, the material and the method for forming the seed layer 361a are not particularly limited. For example, the seed layer 361a may be formed by sputtering. The first plating layer 361b is sacked on the seed layer 361a and may be made of Cu or a Cu alloy. The first plating layer 361b may be formed by electroplating. Yet, the material of the first plating layer 361b is not particularly limited. The second plating layer 361c is stacked on the first plating layer 361b. The second plating layer 361c is disposed between the first plating layer 361b and the solder portion 362 and prevents the first plating layer 361b and the solder portion 362 from reacting with each other. The material of the second plating layer 361c is not particularly limited, and any metals capable of preventing the reaction, such as Ni and Fe, may be selected. In this embodiment, since the first plating layer 361b contains Cu and the solder portion 362 contains Sn, the second plating layer 361c may be made of Ni, for example. The second plating layer 361c of this embodiment may be formed by electroplating. Yet, the material and the method for forming the second plating layer 361c are not particularly limited. Furthermore, the second plating layer 361c may not be essential. The pillar portion 361 has an end surface (facing away from the electrode 34 and located opposite the relevant one of the first obverse surfaces 101, the second obverse surfaces 211 and the third obverse surfaces 221) and the end surface is formed with a recess 361d that is a central portion recessed from the peripheral portion.

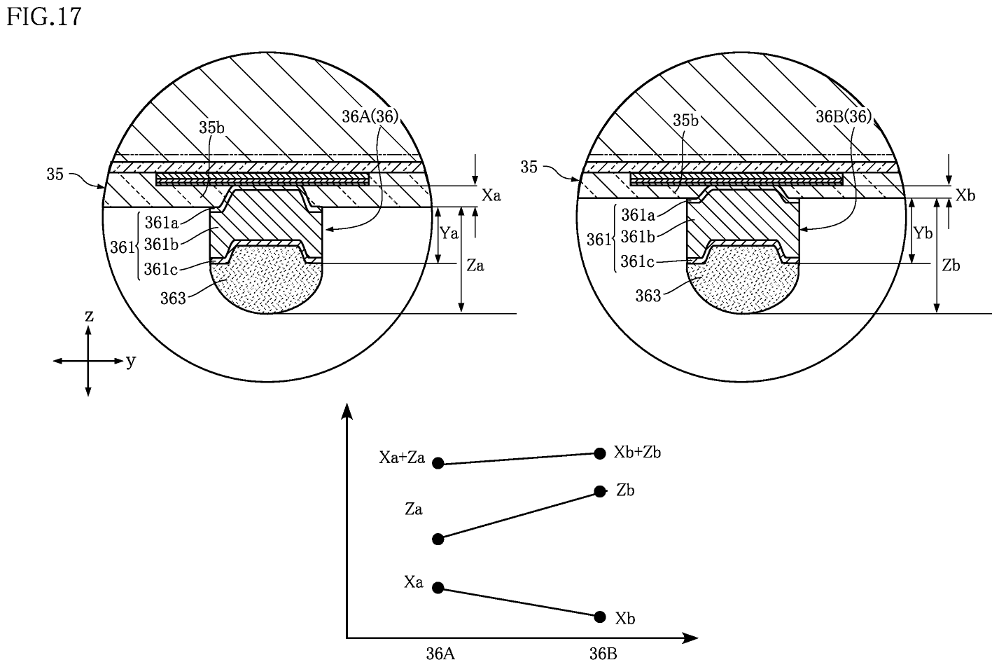

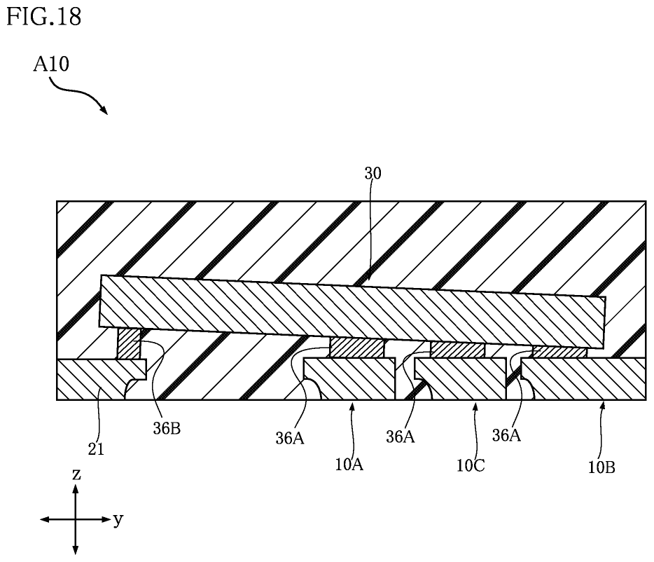

The solder portion 362 is electrically conductive and disposed between the pillar portion 361 and the first obverse surface 101 of a relevant first lead 10A, 10B or 10C, the second obverse surface 211 of a relevant second lead 21 or the third obverse surface 221 of a relevant third lead 22 to provide electrical connection them. In this embodiment, the solder portion 362 is made of solder containing Sn (such as SnAg solder). In this embodiment, a solder layer is formed in advance on the pillar portion 361 by electroplating (see FIG. 17, which will be described later), and this solder layer is melt to form the solder portion 362 when the semiconductor element 30 is mounted on the first leads 10A, 10B and 10C, the second leads 21 and the third leads 22. Yet, the material and method for forming the solder portion 362 are not particularly limited.

The electrode terminals 36 include a plurality of electrode terminal 36A and a plurality of electrode terminals 36B.

The electrode terminals 36A are electrically connected to the switching circuit 321 of the semiconductor layer 32. The electrode terminals 36A are also connected to the first obverse surfaces 101 of the first leads 10A, 10B and 10C. Thus, the first leads 10A, 10B and 10C are electrically connected to the switching circuit 321. The shape of the electrode terminals 36A as viewed in the z direction (the planar shape) is not particularly limited and may be circular, elliptical (oval), rectangular or polygonal as appropriate. In the illustrated example, all the electrode terminal 36A have the same elliptical (oval) shape as viewed in the z direction. As shown in FIG. 5, the longitudinal direction of the electrode terminals 36A (the direction of the major diameter) is parallel to the longitudinal direction of the electrodes 34. In this embodiment, in addition, the longitudinal direction of the electrode terminals 36A is perpendicular to the direction in which the first leads 10A, 10Ca and 10B extend. Yet, the longitudinal direction of the electrode terminals 36A and the direction in which the first leads 10A, 10Ca and 10B extend are not required to satisfy the above-described relation. The dimensions of the electrode terminals 36A are not particularly limited. In one example, the electrode terminals 36A may have a major diameter (y-direction dimension) of 300 μm and a minor diameter (x-direction dimension) of 100 μm.

As indicated by the broken lines in FIG. 2, the electrode terminals 36A are located in the first region 301 of the element obverse surface 30a. The electrode terminals 36 located in the first region 301 are relatively close to each other, and the total area of the electrode terminals 36 (36A) occupy a relatively large percentage of the area of the first region 301. In one non-limiting example, the maximum dimension (the y-direction dimension, for example) of any specific electrode terminal 36 located in the first region 301 is greater than the distance between the specific electrode terminal and another electrode terminal 36 adjacent thereto. In other words, the first region 301 is where the plurality of electrode terminals 36 are densely arranged. Thus, in the electroplating process, the density of electric current applied is relatively low in the first region 301 where the densely arranged electrode terminals 36 are formed. As a result, the pillar portions 361 formed in this region have a relatively small thickness height (the z-direction dimension) Ya from the insulating layer 35 (see FIGS. 14, 15 and 17).

In this embodiment, the insulating layer 35 is thicker in the first region 301. Thus, as shown in FIGS. 14, 15 and 17, each overlapping portion 35b that overlaps with an electrode terminal 36A as viewed in the z direction has a relatively large thickness (the z-direction dimension) Xa.

As indicated by the broken lines in FIG. 2, the electrode terminals 36B are located in the second region 302 of the element obverse surface 30a. The electrode terminals 36B are electrically connected to the control circuit 322 of the semiconductor layer 32. Most of the electrode terminals 36B are connected to the second obverse surface 211 of a second lead 21. The other electrode terminals 36B are connected to the third obverse surface 221 of a third lead 22. Thus, the second leads 21 and the third leads 22 are electrically connected to the control circuit 322. The shape of the electrode terminals 36B as viewed in the z direction (the planar shape) is not particularly limited and may be circular, elliptical (oval), rectangular or polygonal as appropriate. In the illustrated example, the electrode terminals 36B are circular as viewed in the z direction. The dimensions of the electrode terminals 36B are not particularly limited. In one example, the electrode terminals 36B may have a diameter of 100 μm.

The following describes the respective areas of the electrode terminals 36 in plan view (the plane areas). The electrode terminals 36A located in the first region 301 are designed to have a larger plane area than the electrode terminals 36B located in the second region 302. The plane area of each electrode terminal 36 corresponds to the value of electric current flowing through the electrode terminal, so that the value of the electric current that flows through one electrode terminal 36A is larger than that through one electrode terminal 36B. The electrode terminals 36A are formed in the first region 301, which is typically for mounting a power element, such as a power transistor. The electrode terminals 36B are formed in the second region 302, which is typically for mounting a logic element.

The following describes the respective shapes of the electrode terminals in plan view (the plane shapes). The electrode terminals 36A located in the first region 301 preferably have an elliptical shape in plan view as described above, and other preferable shapes include a narrow rectangle. The electrode terminals 36B located in the second region 302 preferably have a circular shape in plan view as described above, and other preferable shapes include a square and a rectangle that is nearly a square. Forming the electrode terminals 36 in these shapes can increase the ratio between the total area of the electrode terminals 36A per unit area and the total area of the electrode terminals 36B per unit area. This consequently increases the ratio of the total value of electric current that flows through the electrode terminals 36A to the total value of electric current that flows the electrode terminals 36B. In this way, the value of the electric current flowing through the electrode terminals 36B per unit area can be increased.

Since the electrode terminals 36B are isolated from each other in the second region 302, the total area of the electrode terminals 36 (36B) occupy a relatively small percentage of the area of the second region 302. In other words, the second region 302 is where the plurality of electrode terminals 36 are sparsely arranged. In one non-limiting example, the maximum dimension (the diameter, for example) of any specific electrode terminal 36 located in the second region 302 is smaller than the distance between that specific electrode terminal and another electrode terminal 36 adjacent thereto. In the electroplating process, the density of electric current applied is relatively high in the second region 302 where the sparsely arranged electrode terminals 36 are formed. As are result, the pillar portions 361 formed in this region have a relatively large thickness height (the z-direction dimension) Yb from the insulating layer 35 (see FIGS. 16 and 17).

In this embodiment, the insulating layer 35 is thinner in the second region 302. Thus, as shown in FIGS. 16 and 17, each overlapping portion 35b that overlaps with an electrode terminal 36B as viewed in the z direction has a relatively small thickness (the z-direction dimension) Xb.

Note that a region in which a plurality of electrode terminals 36 are densely arranged may mean that the electrode terminals 36, when having the same planar shape and the same plane area, are densely arranged in that region. In another instance, when a plurality of electrode terminals 36 have different planar shapes and different plane areas, a region in which a plurality of electrode terminals 36 are densely arranged may mean that the total area of the electrode terminals 36 included in such a dense region occupies a relatively large percentage of the total area of the whole region. On the other hand, a region in which a plurality of electrode terminals 36 are sparsely arranged may mean that the electrode terminals 36, when having the same planar shape and the same plane area, are sparsely arranged in that region. In another instance, when a plurality of electrode terminals 36 have different planar shapes and different plane areas, a region in which a plurality of electrode terminals 36 are sparsely arranged may mean that the total area of the electrode terminals 36 included in such a sparse region occupies a relatively small percentage of the total area of the whole region.

FIG. 17 illustrates the dimension differences between the electrode terminals 36 formed at different arrangement densities. FIG. 17 is an enlarged sectional view showing a portion of the semiconductor element 30 before mounting. The upper left of the figure shows a portion around an electrode terminal 36A included in the first region 301 and corresponds to FIG. 15. The upper right of the figure shows a portion around an electrode terminal 36B included in the second region 302 and corresponds to FIG. 16.

The electrode terminal 36A includes a pillar portion 361 having a height Ya measured from the insulating layer 35, and the electrode terminal 36B includes a pillar portion 361 having a height Yb measured from the insulating layer 35, where the height Ya is smaller than the height Yb (Ya<Yb). In addition, each electrode terminal includes a solder layer 363 also formed by electroplating on the pillar portion 361. The electrode terminal 36A including the solder layer 363 has a height Za measured from the insulating layer 35, and the electrode terminal 36B including the solder layer 363 has a height Zb measured from the insulating layer 35, where the height Za is smaller than the height Zb (Za<Zb). Yet, in this embodiment, each overlapping portion 35b that overlaps with an electrode terminal 36A has a thickness Xa, and each overlapping portion 35b that overlaps with the electrode terminal 36B has a thickness Xb, where the thickness Xa is larger than the thickness Xb (Xa>Xb). Accordingly, when measured from the relevant electrodes 34, the height of the electrode terminal 36A (Xa+Za) is closer to the height of the electrode terminal 36B (Xb+Zb). The thicknesses Xa and Xb are determined to cancel out the difference between the height Za and the height Zb to make the height (Xa+Za) and the height (Xb+Zb) raguly equal.

As shown in FIGS. 14 to 16, a plating layer 60 is disposed between the solder portion 362 of each electrode terminal 36 and the first obverse surface 101 of a relevant first lead 10A, 10B or 10C, the second obverse surface 211 of a relevant second lead 21 or the third obverse surface 221 of a relevant third lead 22, to provide electrical connection therebetween. Each plating layer 60 serves to prevent the first lead 10A, 10B or 10C, the second lead 21 or the third lead 22 and the solder portion 362 from reacting with each other. The material of the plating layer 60 is not particularly limited, and any metals, such as Ni and Fe, capable of preventing the reaction may be selected. In the illustrated example, each plating layer 60 coats a portion of the first obverse surface 101, the second obverse surface 211 or the third obverse surface 221, rather than the entirety of the first obverse surface 101, the second obverse surface 211 or the third obverse surface 221.

Each plating layer 60 of this embodiment includes a first layer 61, a second layer 62 and a third layer 63. The first layer 61 is disposed on the first obverse surface 101 of a relevant first lead 10A, 10B or 10C, the second obverse surface 211 of a relevant second lead 21, or the third obverse surface 221 of a relevant third lead 22. In this embodiment, the first leads 10A, 10B and 10C, the second leads 21 and the third leads 22 contain Cu, and the solder portion 362 contains Sn, so that the first layer 61 may be made of Ni, for example. The second layer 62 is formed on the first layer 61. The material of the second layer 62 is not particularly limited and may include Pd. The third layer 63 is formed on the second layer 62. The material of the third layer 63 is not particularly limited and may include Au. The method for forming the plating layers 60 is not particularly limited. Furthermore, the plating layers 60 may be omitted.

The shape of the plating layers 60 as viewed in the z direction (the planar shape) is not particularly limited. For instance, as shown in FIGS. 2, 3, 14 and 15, the plating layers 60 provided for the electrode terminals 36A have an oval shape as viewed in the z direction (the planar shape). As shown in FIGS. 2, 3 and 16, on the other hand, the plating layers 60 provided for the electrode terminals 36B have a circular shape as viewed in the z direction (the planar shape). As shown in FIGS. 14 to 16, in this embodiment, each electrode terminal 36 as viewed in the z direction is located inside the relevant plating layer 60. In the illustrated example, the third layer 63 of each plating layer 60 has a relatively high solder wettability. The solder portion 362 of this example has a cross-sectional area transverse to the z direction that gradually increases as proceeding from the position closer to the pillar portion 361 toward the position closer to the plating layer 60 in the z direction. The solder portion 362 is formed with solder fillet. With the solder fillet, the electrode terminal 36 and the plating layer 60 are more reliably bonded.

The sealing resin 40 covers the entirety of the semiconductor element 30 and portions of the first leads 10A, 10B and 10C, the second leads 21 and the third leads 22. The sealing resin 40 may be made of a material containing a black epoxy resin, for example. The material of the sealing resin 40 is not particularly limited. The sealing resin 40 is rectangular as viewed in the z direction and includes a top surface 41, a bottom surface 42, a pair of first side surfaces 431 and a pair of second side surfaces 432 as shown in FIGS. 6 to 9.

As shown in FIGS. 10 to 13, the top surface 41 faces in the same direction as the first obverse surfaces 101 of the first leads 10A, 10B and 10C in the z direction. As shown in FIGS. 6 to 9, the bottom surface 42 faces away from the top surface 41. As shown in FIG. 4, the first reverse surfaces 102 of the first leads 10A, 10B and 10C, the second reverse surfaces 212 of the second leads 21 and the third reverse surfaces 222 of the third leads 22 are exposed on the bottom surface 42.

As shown in FIGS. 8 and 9, the pair of first side surfaces 431 are connected to the top surface 41 and the bottom surface 42 and face in the x direction. The pair of first side surfaces 431 are spaced apart from each other in the x direction. As shown in FIGS. 6, 7 and 11 to 13, the first end surfaces 121 of the first leads 10A, 10B and 10C, the fourth end surfaces 214 of the second leads 21, and the third end surfaces 223 of the third lead 22 are exposed on and flush with the first side surfaces 431.

As shown in FIGS. 6 and 7, the pair of second side surfaces 432 are connected to the top surface 41, the bottom surface 42, and the pair of first side surfaces 431 and face in the y direction. The pair of second side surfaces 432 are spaced apart from each other in the y direction. As shown in FIG. 10, the second end surfaces 213 of the second leads 21 are exposed on and flush with the second side surface 432 that is located in the first sense of the y direction. The sub-end surfaces 131 of the first lead 10B are exposed on and flush with the second side surface 432 that is located in the second sense of the y direction.

The following describes advantages of the semiconductor device A10.

According to this embodiment, the overlapping portions 35b overlapping with the electrode terminals 36A densely arranged in the first region 301 are relatively thick, so that the thickness Xa of such an overlapping portion is greater than the thickness Xb of the overlapping portions 35b overlapping with the electrode terminal 36B sparsely arranged in the second region 302. Therefore, although the height Za of the electrode terminals 36A may be smaller than the height Zb of the electrode terminal 36B due to the current density variations in electroplating, the overlapping portions can reduce the difference between the height of the electrode terminals 36A from the relevant electrodes 34 (Xa+Za) and the height of the electrode terminals 36B from the relevant electrodes 34 (Xb+Zb). In this way, variations in the height of the electrode terminals 36 from the relevant electrodes 34 can be compensated for.

Actual measurements were made on the semiconductor element 30 to measure the dimensions of the electrode terminals 36A and the electrode terminal 36B. The average height Za of the electrode terminals 36A from the insulating layer 35 was 68.0 μm, whereas the average height Zb of the electrode terminals 36B from the insulating layer 35 was 74.0 μm. Thus, the difference was 6.0 (74.0−68.0) μm. The thickness Xa of the overlapping portions 35b overlapping with the electrode terminal 36A was 10.2 μm, whereas the thickness Xb of the overlapping portions 35b overlapping with the electrode terminals 36B was 6.5 μm. Accordingly, the height (Xa+Za) of the electrode terminals 36A from the insulating layer 35 was 78.2 (68.0+10.2) μm, whereas the height (Xa+Za) of the electrode terminals 36B from the insulating layer 35 was 80.5 (74.0+6.5) μm. Thus, the difference was 2.3 (80.5−8.2) μm. This shows that the different thicknesses of the overlapping portions 35b cancel out the difference in the height of the electrode terminals 36 caused by the current density variations in electroplating. As a result, the heights of the electrode terminals 36 from the relevant electrodes 34 are made more uniform.

As described above, variations in the height of the electrode terminals 36 are reduced but may not be completely eliminated. In this embodiment, the electrode terminals 36A are formed in the first region 301 and the electrode terminals 36B are formed in the second region 302 as shown in FIG. 2. The first region 301 is offset in the second sense of the y direction (to the right in FIG. 2) in the element obverse surface 30a, and the second region 302 is offset in the first sense of the y direction (to the left in FIG. 2) in the element obverse surface 30a. The arrangement of the first region 301 and the second region 302 is not symmetrical along the y direction. Although the electrode terminals 36A may be higher than the electrode terminals 36B, or vice versa, the semiconductor element 30 can be bonded without connection failure in a position inclined relative to a plane perpendicular to the z direction.

FIG. 18 is a schematic sectional view of the semiconductor device A10 where variations in the height of the electrode terminals 36 are reduced but not completely. In FIG. 18, the electrode terminals 36A are lower than the electrode terminal 36B due to, for example, the insufficient thickness of the insulating layer 35 in the first region 301. Despite the height difference, the first leads 10A, 10B and 10C can be bonded to the electrode terminals 36A without connection failure, by mounting the semiconductor element 30 in an inclined position. For purposes of clarity, the height difference of the electrode terminals 36 and the inclination of the semiconductor element 30 shown in FIG. 18 are greatly exaggerated.

According to this embodiment, each pillar portion 361 includes a second plating layer 361c at a contact position with the solder portion 362. This prevents a reaction between the first plating layer 361b containing Cu and the solder portion 362 containing Sn. This consequently prevents the formation of voids at the joint interfaces between the pillar portion 361 and the solder portion 362. As a result, the risk of crack formation is reduced. According to the present embodiment, in addition, a plating layer 60 containing Ni is disposed between the first obverse surface 101 of a relevant first lead 10A, 10B or 10C, the second obverse surface 211 of a relevant second lead 21 or the third obverse surface 221 of a relevant third lead 22 and the solder portion 362 of a relevant electrode terminal 36. This prevents a reaction between the relevant first lead 10A, 10B or 10C, the relevant second lead 21 or the relevant third lead 22 and the solder portion 362 containing Sn. This consequently prevents the formation of voids at the joint interfaces between the relevant first lead 10A, 10B or 10C, the relevant second lead 21 or the relevant third lead 22 and the solder portion 362. As a result, the risk of crack formation is reduced.

According to this embodiment, the semiconductor element 30 is flip-chip mounted on the first leads 10A, 10B and 10C, the second leads 21 and the third leads 22. This enables low-resistance electrical paths and low profile as compared with a semiconductor device with wire bonded the electrodes 34 and the leads. Also, flip-chip mounting enables a larger semiconductor element 30 to be mounted on the sealing resin 40 of the same size in plan view, and reversely, the semiconductor element 30 of the same size to be mounted on the sealing resin 40 of smaller outer dimensions.

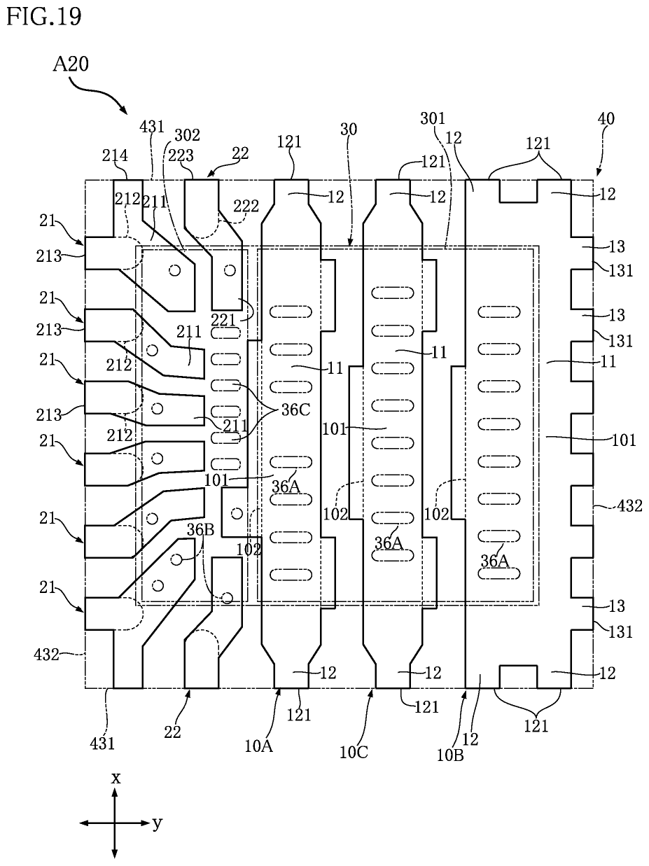

FIGS. 19 to 26 show other embodiments of the present disclosure. In these figures, similar or identical components to those of the embodiment described above are denoted by the same reference numerals.

### Second Embodiment

FIG. 19 is a view for illustrating a semiconductor device A20 according to a second embodiment of the present disclosure. FIG. 19 is a plan view of the semiconductor device A20 and corresponds to FIG. 3. For convenience, FIG. 19 shows the sealing resin 40 and the semiconductor element 30 as transparent. The outlines of the sealing resin 40 and the semiconductor element 30 are shown in phantom (chain double-dashed lines). The semiconductor device A20 of this embodiment differs from the first embodiment in that the semiconductor element 30 additionally includes a plurality of electrode terminals 36C.

The semiconductor element 30 of this embodiment additionally includes the electrode terminals 36C. The electrode terminals 36C are similar in configuration to the electrode terminals 36A and 36B. The electrode terminals 36C are located in the second region 302 of the element obverse surface 30a. The electrode terminals 36C are “dummy electrode terminals” not connected to any of the first leads 10A, 10B and 10C, the second leads 21 and the third leads 22. In contrast, the electrode terminals 36A and 36B are “functional electrode terminals” connected to the relevant leads. Although the shape as viewed in the z direction (the planar shape) is not particularly limited, the electrode terminals 36C having a large area are preferable. In this embodiment, the electrode terminals 36C has an oval shape. Providing the electrode terminals 36C increases the total area of the electrode terminals 36 formed in the second region 302, ensuring that the density of electric current applied for electroplating is suppressed. The electrode terminals 36B formed in this way are smaller in the height Zb from the insulating layer 35 (the height Yb of the pillar portions 361 from the insulating layer 35) than those formed without the electrode terminals 36C.

Also in this embodiment, the thickness Xa of each overlapping portion 35b that overlaps with an electrode terminal 36A is greater than the thickness Xb of each overlapping portion 35b that overlaps with an electrode terminal 36B or 36C. Therefore, although the height Za of the electrode terminals 36A may be smaller than the height Zb of the electrode terminal 36B due to the current density variations in electroplating, the overlapping portions can reduce the difference between the height of the electrode terminals 36A from the relevant electrodes 34 (Xa+Za) and the height of the electrode terminals 36B from the relevant electrodes 34 (Xb+Zb). In this way, variations in the height of the electrode terminals 36 from the relevant electrodes 34 can be compensated for.

Providing the electrode terminals 36C in the second region 302 increases the total area of the electrode terminals 36 formed in the second region 302, ensuring that the density of electric current applied for electroplating is suppressed. The electrode terminals 36B formed in this way are smaller in the height Zb from the insulating layer 35 than those formed without the electrode terminals 36C. In this way, variations in the height of the electrode terminals 36 can be reduced.

### Third Embodiment

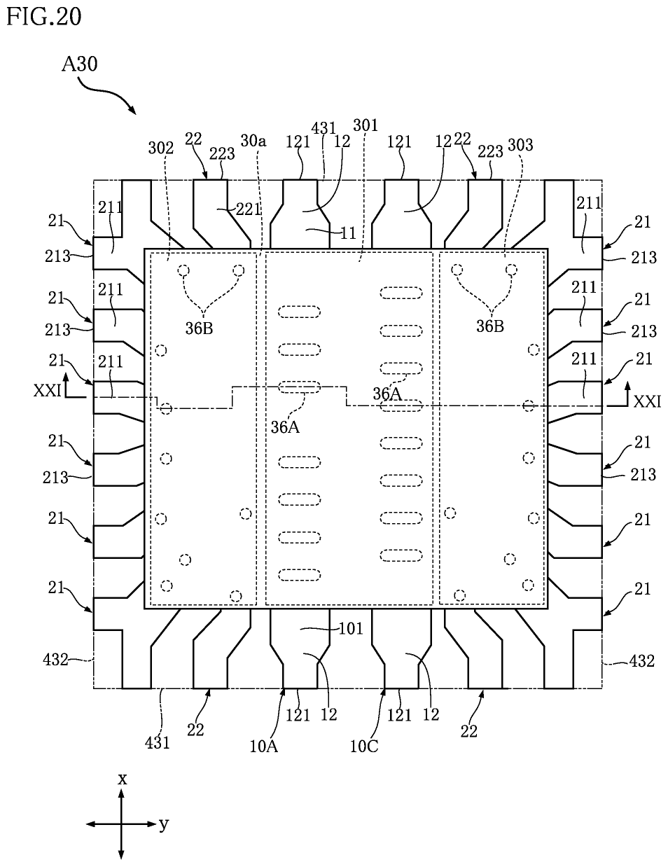

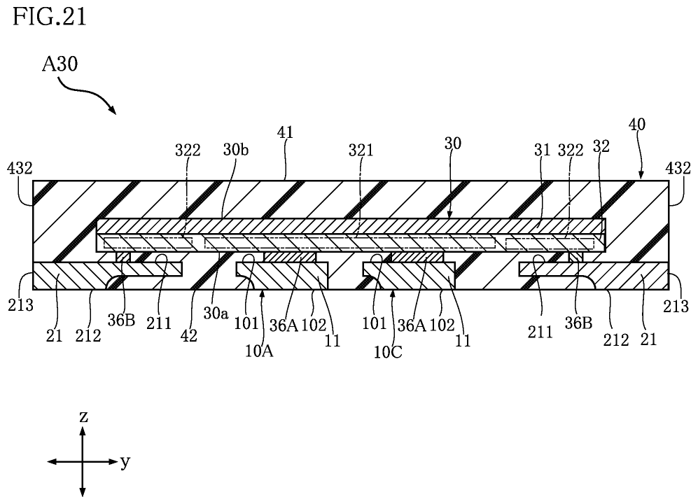

FIGS. 20 and 21 are views for illustrating a semiconductor device A30 according to a third embodiment of the present disclosure. FIG. 20 is a plan view of the semiconductor device A30 and corresponds to FIG. 2. For convenience, FIG. 20 shows the sealing resin 40 as transparent, and the outline of the sealing resin 40 is shown in phantom (chain double-dashed line). FIG. 21 is a sectional view taken along line XXI-XXI of FIG. 20 and corresponds to FIG. 10. The semiconductor device A30 of this embodiment differs from the first embodiment in the arrangement of the electrode terminals 36 in the semiconductor element 30.

The semiconductor device A30 does not include the first lead 10B and instead includes a plurality of second leads 21 and a pair of third leads 22. The element obverse surface 30a additionally includes a third region 303 as indicated by the broken line in FIG. 20. The first region 301 is located at the center in the y direction, the second region 302 is offset in the first sense of the y direction, and the third region is offset in the second sense of the y direction. Similarly to the second region 302, the third region 303 includes a plurality of electrode terminals 36B each of which is connected to a relevant second lead 21 or a relevant third lead 22. In the third region 303, the electrode terminals 36 are isolated from each other, so that the electrode terminals 36 (36B) occupy a relatively small percentage of the area of the third region 303. In other words, the third region 303 is where the plurality of electrode terminals 36 are sparsely arranged. In this embodiment, the second region 302 and the third region 303, which are sparse with the electrode terminals 36, are located on the opposite sides of the first region 301, which is dense with the electrode terminals 36, in the y direction. That is, the sparse regions and the dense region of the electrode terminals 36 are symmetrically arranged along the y direction.

Also in this embodiment, the thickness Xa of each overlapping portion 35b that overlaps with an electrode terminal 36A is greater than the thickness Xb of each overlapping portion 35b that overlaps with an electrode terminal 36B. Therefore, although the height Za of the electrode terminals 36A may be smaller than the height Zb of the electrode terminal 36B due to the current density variations in electroplating, the overlapping portions can reduce the difference between the height of the electrode terminals 36A from the relevant electrodes 34 (Xa+Za) and the height of the electrode terminals 36B from the relevant electrodes 34 (Xb+Zb). In this way, variations in the height of the electrode terminals 36 from the relevant electrodes 34 can be compensated for.

In this embodiment, the sparse regions and the dense region of the electrode terminals 36 are symmetrically arranged along the y direction. This arrangement is more desirable in terms of stress, as compared to the asymmetrical arrangement of the sparse and dense regions of the electrode terminals 36.

### Fourth Embodiment

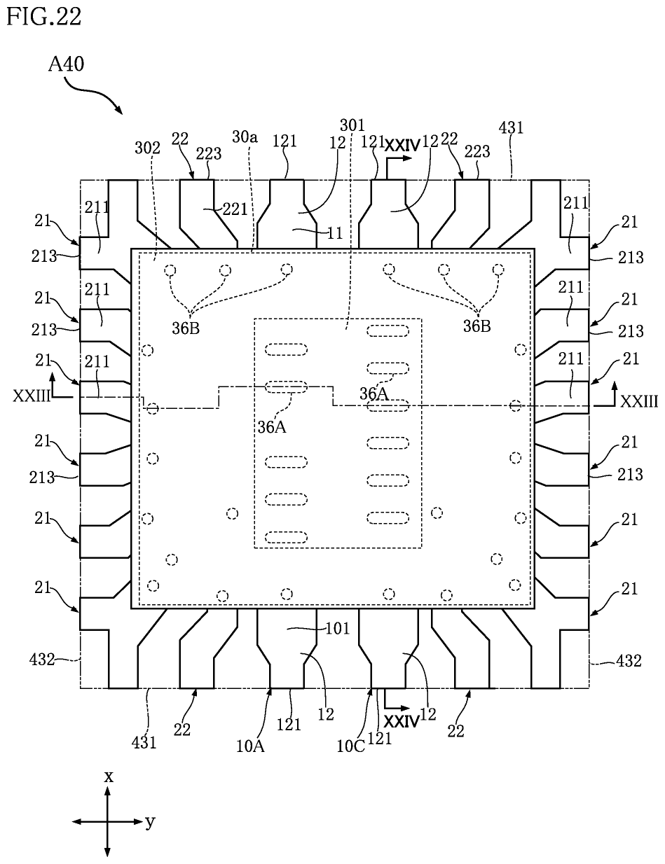

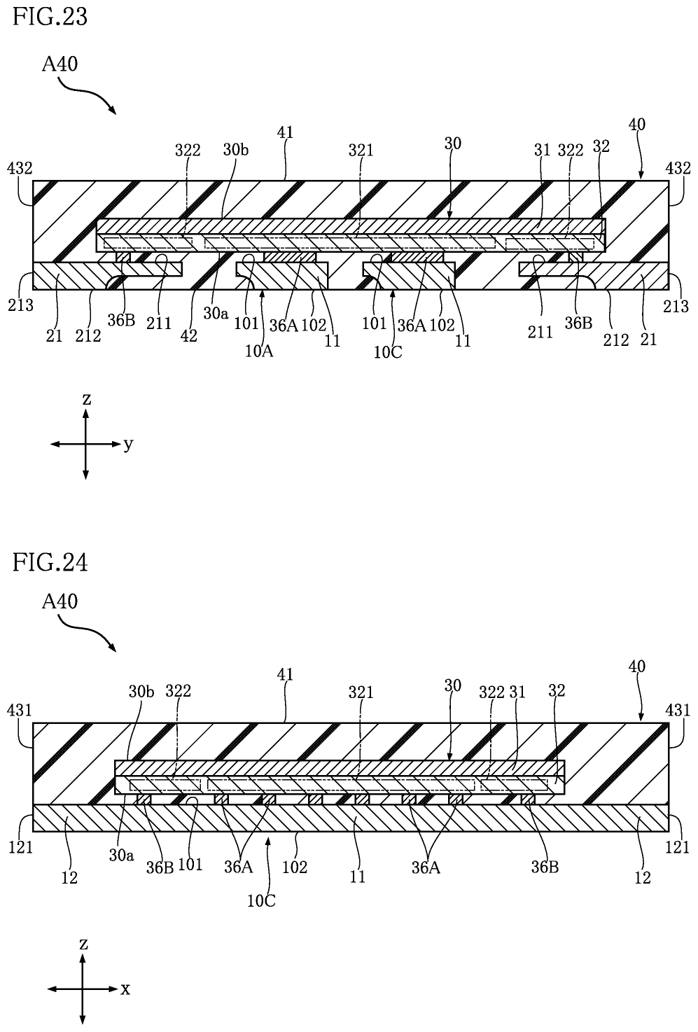

FIGS. 22 to 24 are views for illustrating a semiconductor device A40 according to a fourth embodiment of the present disclosure. FIG. 22 is a plan view of the semiconductor device A40 and corresponds to FIG. 2. For convenience, FIG. 22 shows the sealing resin 40 as transparent, and the outline of the sealing resin 40 is shown in phantom (chain double-dashed line). FIG. 23 is a sectional view taken along line XXIII-XXIII of FIG. 22 and corresponds to FIG. 10. FIG. 24 is a sectional view taken along line XXIV-XXIV of FIG. 22 and corresponds to FIG. 11. The semiconductor device A40 of this embodiment differs from the first embodiment in the arrangement of the electrode terminals 36 in the semiconductor element 30.

The semiconductor device A40 does not include the first lead 10B and instead includes a plurality of second leads 21 and a pair of third leads 22. As indicated by the broken lines in FIG. 22, the element obverse surface 30a includes a first region 301 in which a plurality of electrode terminals 36 are densely arranged and a second region 302 in which a plurality of electrode terminals 36 are sparsely arranged. In this embodiment, the first region 301 is located at the center of the element obverse surface 30a, and the second region 302 surrounds the first region 301. That is, the sparse regions and the dense region of the electrode terminals 36 are symmetrically arranged along the y direction and also along the x direction.

Also in this embodiment, the thickness Xa of each overlapping portion 35b that overlaps with an electrode terminal 36A is greater than the thickness Xb of each overlapping portion 35b that overlaps with an electrode terminal 36B. Therefore, although the height Za of the electrode terminals 36A may be smaller than the height Zb of the electrode terminal 36B due to the current density variations in electroplating, the overlapping portions can reduce the difference between the height of the electrode terminals 36A from the relevant electrodes 34 (Xa+Za) and the height of the electrode terminals 36B from the relevant electrodes 34 (Xb+Zb). In this way, variations in the height of the electrode terminals 36 from the relevant electrodes 34 can be compensated for.

In this embodiment, the sparse regions and the dense region of the electrode terminals 36 are symmetrically arranged along the y direction and also along the x direction. This arrangement is more desirable in terms of stress, as compared to the asymmetrical arrangement of the sparse and dense regions of the electrode terminals 36.

As shown in the third embodiment and the fourth embodiment, variations in the height of the electrode terminals 36 can be reduced by forming the insulating layer 35 with the overlapping portions 35b of appropriate thicknesses. In such a case, it is not necessary to arrange the sparse and dense regions of the electrode terminals 36 asymmetrically. The arrangement of the sparse and dense regions of the electrode terminals 36 can be designed more freely, providing greater design flexibility for the semiconductor element 30.

### Fifth Embodiment

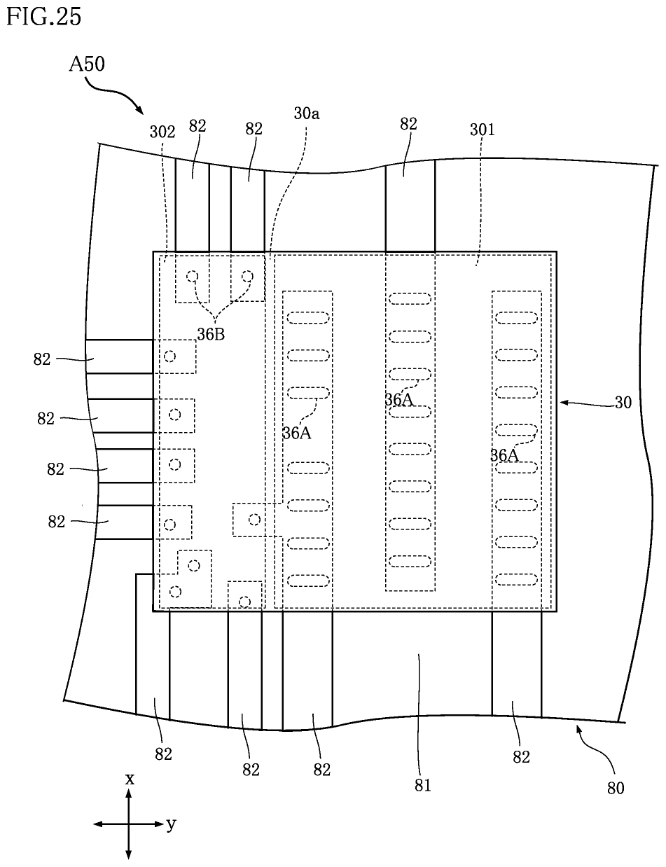

FIG. 25 is a view for illustrating a semiconductor device A50 according to a fifth embodiment of the present disclosure. FIG. 25 is a plan view showing a portion of the semiconductor device A50 and corresponds to FIG. 2. For convenience, FIG. 25 shows the sealing resin 40 as transparent. The semiconductor device A50 of this embodiment differs from the first embodiment in that the semiconductor element 30 is mounted on a substrate instead of the leads.

In the first to fourth embodiments, the semiconductor element 30 is mounted on the first leads 10A, 10B and 10C, the second leads 21 and the third leads 22, and the electrode terminals 36 are connected to those leads. Yet, the semiconductor element 30 can be connected to a conducting member other than leads. In the fifth embodiment, the semiconductor element 30 of the semiconductor device A50 is mounted on a wiring board and the electrode terminals 36 are connected to the wiring of the wiring board.

The semiconductor device A50 does not include the first leads 10A, 10B and 10C, the second leads 21 and the third leads 22 and instead includes a wiring board 80. The wiring board 80 includes a substrate 81 and a plurality of wires 82. The substrate 81 is a rectangular plate made of a grass epoxy resin or a ceramic material, for example. The shape and the material of the substrate 81 are not limited. The wires 82 are made of Cu, for example, and formed on the substrate 81. The shape and the material of the wires 82 are not limited.

The semiconductor element 30 is flip-chip bonded with the element obverse surface 30a directed toward the wiring board 80. The electrode terminals 36 are appropriately connected to the wires 82 of the wiring board 80. The sealing resin 40 (omitted in FIG. 25) covers the entirety of the semiconductor element 30 and at least a portion of the wiring board 80. The wiring board 80 may have one or more electronic components mounted thereon and/or bonded to a lead for mounting the semiconductor device A50 on another wiring board.

Also in this embodiment, the thickness Xa of each overlapping portion 35b that overlaps with an electrode terminal 36A is greater than the thickness Xb of each overlapping portion 35b that overlaps with an electrode terminal 36B. Therefore, although the height Za of the electrode terminals 36A may be smaller than the height Zb of the electrode terminal 36B due to the current density variations in electroplating, the overlapping portions can reduce the difference between the height of the electrode terminals 36A from the relevant electrodes 34 (Xa+Za) and the height of the electrode terminals 36B from the relevant electrodes 34 (Xb+Zb). In this way, variations in the height of the electrode terminals 36 from the relevant electrodes 34 can be compensated for.

### Sixth Embodiment

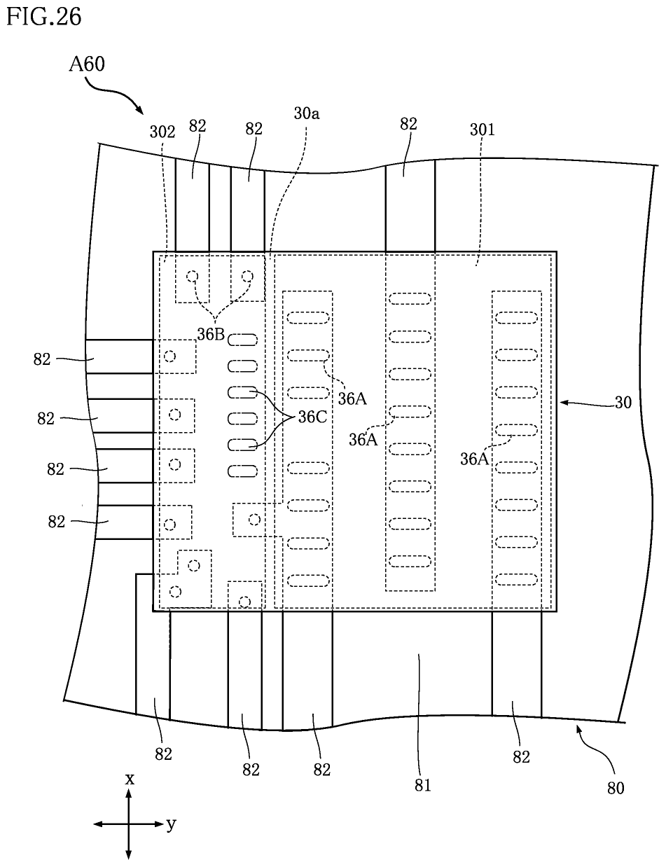

FIG. 26 is a view for illustrating a semiconductor device A60 according to a sixth embodiment of the present disclosure. FIG. 26 is a plan view showing a portion of the semiconductor device A60 and corresponds to FIG. 25. For convenience, FIG. 26 shows the sealing resin 40 as transparent. The semiconductor device A60 of this embodiment differs from the fifth embodiment in that the semiconductor element 30 includes a plurality of dummy electrode terminals 36C.

The semiconductor element 30 of this embodiment is similar to the semiconductor element 30 of the second embodiment and includes the electrode terminals 36C in the second region 302 of the element obverse surface 30a. The wiring board 80 includes no wires 82 at locations opposite the electrode terminals 36C. Consequently, the electrode terminals 36C are not connected to any wiring 82 and thus out of conduction.

Also in this embodiment, the thickness Xa of each overlapping portion 35b that overlaps with an electrode terminal 36A is greater than the thickness Xb of each overlapping portion 35b that overlaps with an electrode terminal 36B or 36C. Therefore, although the height Za of the electrode terminals 36A may be smaller than the height Zb of the electrode terminal 36B the current density variations in electroplating, the overlapping portions can reduce the difference between the height of the electrode terminals 36A from the relevant electrodes 34 (Xa+Za) and the height of the electrode terminals 36B from the relevant electrodes 34 (Xb+Zb). In this way, variations in the height of the electrode terminals 36 from the relevant electrodes 34 can be compensated for.

Providing the electrode terminals 36C in the second region 302 increases the total area of the electrode terminals 36 formed in the second region 302, ensuring that the density of electric current applied for electroplating is suppressed. The electrode terminals 36B formed in this way are smaller in the height Zb from the insulating layer 35 than those formed without the electrode terminals 36C. In this way, variations in the height of the electrode terminals 36 can be reduced.

The semiconductor element and the semiconductor device according to the present disclosure are not limited to those described in the foregoing embodiments. Various design changes can be made to the specific configuration of each part of the semiconductor element and the semiconductor device according to the present disclosure.

Clause 1.

A semiconductor element comprising:

an element obverse surface and an element reverse surface facing away from each other in a thickness direction;

a plurality of electrodes disposed on the element obverse surface;

an insulating layer disposed on the element obverse surface; and

a plurality of electrode terminals each in contact with one of the plurality of electrodes and partly overlap with the insulating layer as viewed in the thickness direction,

wherein the insulating layer includes a plurality of openings and a plurality of overlapping portions adjoining the plurality of openings, respectively, the plurality of openings exposing the plurality of electrodes, respectively, the plurality of overlapping portions overlapping with the plurality of electrodes, respectively, as viewed in the thickness direction,

the plurality of electrode terminals are in contact with the plurality of electrodes, respectively, through the plurality of openings, while also overlapping with the plurality of overlapping portions, respectively, as viewed in the thickness direction,

the plurality of electrode terminals include a plurality of first electrode terminals that are densely arranged as viewed in the thickness direction and a plurality of second electrode terminals that are sparsely arranged as viewed in the thickness direction, and

each of the overlapping portions that overlaps with one of the plurality of first electrode terminals has a greater dimension in the thickness direction than each of the overlapping portions that overlaps with one of the plurality of second electrode terminals.

Clause 2.

The semiconductor element according to Clause 1, wherein each of the plurality of electrode terminals includes a pillar portion being held in contact with a relevant one of the plurality of electrodes and containing Cu.

Clause 3.

The semiconductor element according to Clause 2, wherein the pillar portion includes an end surface opposite form the relevant electrode, and the end surface includes a peripheral portion and a central portion recessed from the peripheral portion.

Clause 4.

The semiconductor element according to Clause 2 or 3, wherein the pillar portion includes a seed layer in contact with the relevant electrode and a plating layer disposed on the seed layer.

Clause 5.

The semiconductor element according to Clause 4, wherein the plating layer includes a first plating layer made of Cu and a second plating layer made of Ni.

Clause 6.

The semiconductor element according to any one of Clauses 2 to 5, wherein each of the electrode terminals includes a solder portion in contact with the pillar portion.

Clause 7.

The semiconductor element according to any one of Clauses 1 to 6, wherein the insulating layer contains a phenolic resin.

Clause 8.

The semiconductor element according to any one of Clauses 1 to 7, wherein the element obverse surface includes a first region in which the plurality of first electrode terminals are arranged and a second region in which the plurality of second electrode terminals are arranged, while also including a first edge and a second edge spaced apart from each other in a first direction perpendicular to the thickness direction,

the first region is located on a side of the element obverse surface closer to the first edge, and

the second region is located on a side of the element obverse surface closer to the second edge.

Clause 9.

The semiconductor element according to any one of Clauses 1 to 7, wherein the element obverse surface includes a first region in which the plurality of first electrode terminals are arranged and a second region in which the plurality of second electrode terminals are arranged,

the first region is located at a center of the element obverse surface, and

the second region surrounds the first region.

Clause 10.

The semiconductor element according to any one of Clauses 1 to 7, wherein the element obverse surface includes a first region in which the plurality of first electrode terminals are arranged, and a second region and a third region in each of which the plurality of second electrode terminals are arranged, and

the second region and the third region are located on opposite sides in a first direction perpendicular to the thickness direction with respect to the first region.

Clause 11.

The semiconductor element according to any one of Clauses 1 to 10, wherein each of the plurality of first electrode terminals is elliptical as viewed in thickness direction, and

each of the plurality of second electrode terminals is circular as viewed in thickness direction.

Clause 12.

The semiconductor element according to any one of Clauses 1 to 11, wherein each of the plurality of electrodes contains Cu.

Clause 13.

The semiconductor element according to any one of Clauses 1 to 12, wherein each of the plurality of electrodes includes a first layer made of Cu, a second layer made of Ni and a third layer made of Pd.

Clause 14.

A semiconductor device comprising:

a semiconductor element according to any one of Clauses 1 to 13; and

a sealing resin covering the semiconductor element.

Clause 15.

The semiconductor device according to Clause 14, further comprising a plurality of leads,

wherein the plurality of electrode terminals includes a dummy electrode terminal not bonded to any of the plurality of leads and a plurality of functional electrode terminals other than the dummy electrode terminal, and each of the plurality of functional electrode terminals is bonded to a relevant one of the plurality of leads.

Clause 16.

The semiconductor device according to Clause 15, further comprising a plating layer disposed between each of the plurality of functional electrode terminals and the relevant one of the leads and containing Ni.

Clause 17.

The semiconductor device according to Clause 14, further comprising a substrate and a plurality of wires disposed on the substrate,

wherein each of the plurality of wires is bonded to one of the plurality of electrode terminals, and

the plurality of electrode terminals include a dummy electrode terminal not bonded to any of the plurality of wires.

REFERENCE NUMERALS

| | | |
|---|---|---|
| A10, A20, A30, A40, A50, A60: | | |
| Semiconductor device | | |
| 10, 10A, 10B, 10C: First lead | | |
| 11: Main section | 12: Side section | 13: Projection |
| 101: First obverse surface | 102: First reverse surface | |
| 121: First end surface | 131: Sub-end surface | |
| 21: Second lead | 211: Second obverse surface | |
| 212: Second reverse surface | 213: Second end surface | |
| 214: Fourth end surface | 22: Third lead | |
| 221: Third obverse surface | 222: Third reverse surface | |
| 223: Third end surface | 30: Semiconductor element | |
| 30a: Element obverse surface | 301: First region | |
| 302: Second region | 303: Third region | |
| 30b: Element reverse surface | 31: Semiconductor substrate | |
| 32: Semiconductor layer | 321: Switching circuit | |
| 322: Control circuit | 33: Passivation film | |
| 34: Electrode | 34a: First layer | 34b: Second layer |
| 34c: Third layer | 35: Insulating layer | |
| 35a: Opening | 35b: Overlapping portion | |
| 36, 36A, 36B, 36C: Electrode terminal | | |
| 361: Pillar portion | 361a: Seed layer | |
| 361b: First plating layer | 361c: Second plating layer | |
| 361d: Recess | 362: Solder portion | |
| 363: Solder layer | 40: Sealing resin | |
| 41: Top surface | 42: Bottom surface | 431: First side surface |
| 432: Second side surface | 60: Plating layer | |
| 61: First layer | 62: Second layer | 63: Third layer |
| 80: Wiring board | 81: Substrate | 82: Wire |

1. A semiconductor element comprising:
an element obverse surface and an element reverse surface facing away from each other in a thickness direction;
a plurality of electrodes disposed on the element obverse surface;
an insulating layer disposed on the element obverse surface; and
a plurality of electrode terminals each being held in contact with one of the plurality of electrodes and partly overlapping with the insulating layer as viewed in the thickness direction,
wherein the insulating layer includes a plurality of openings and a plurality of overlapping portions adjoining the plurality of openings, respectively, the plurality of openings exposing the plurality of electrodes, respectively, the plurality of overlapping portions overlapping with the plurality of electrodes, respectively, as viewed in the thickness direction,
the plurality of electrode terminals are in contact with the plurality of electrodes, respectively, through the plurality of openings, while also overlapping with the plurality of overlapping portions, respectively, as viewed in the thickness direction,
the plurality of electrode terminals include a plurality of first electrode terminals that are densely arranged as viewed in the thickness direction and a plurality of second electrode terminals that are sparsely arranged as viewed in the thickness direction, and
each of the overlapping portions that overlaps with one of the plurality of first electrode terminals has a greater dimension in the thickness direction than each of the overlapping portions that overlaps with one of the plurality of second electrode terminals.

2. The semiconductor element according to claim 1, wherein each of the plurality of electrode terminals includes a pillar portion being held in contact with a relevant one of the plurality of electrodes and containing Cu.

3. The semiconductor element according to claim 2, wherein the pillar portion includes an end surface opposite form the relevant electrode, and the end surface includes a peripheral portion and a central portion recessed from the peripheral portion.

4. The semiconductor element according to claim 2, wherein the pillar portion includes a seed layer in contact with the relevant electrode and a plating layer disposed on the seed layer.

5. The semiconductor element according to claim 4, wherein the plating layer includes a first plating layer made of Cu and a second plating layer made of Ni.

6. The semiconductor element according to claim 2, wherein each of the electrode terminals includes a solder portion in contact with the pillar portion.

7. The semiconductor element according to claim 1, wherein the insulating layer contains a phenolic resin.

8. The semiconductor element according to claim 1, wherein the element obverse surface includes a first region in which the plurality of first electrode terminals are arranged and a second region in which the plurality of second electrode terminals are arranged, while also including a first edge and a second edge spaced apart from each other in a first direction perpendicular to the thickness direction,
the first region is located on a side of the element obverse surface closer to the first edge, and
the second region is located on a side of the element obverse surface closer to the second edge.

9. The semiconductor element according to claim 1, wherein the element obverse surface includes a first region in which the plurality of first electrode terminals are arranged and a second region in which the plurality of second electrode terminals are arranged,
the first region is located at a center of the element obverse surface, and
the second region surrounds the first region.

10. The semiconductor element according to claim 1, wherein the element obverse surface includes a first region in which the plurality of first electrode terminals are arranged, and a second region and a third region in each of which the plurality of second electrode terminals are arranged, and
the second region and the third region are located on opposite sides in a first direction perpendicular to the thickness direction with respect to the first region.

11. The semiconductor element according to claim 1, wherein each of the plurality of first electrode terminals is elliptical as viewed in thickness direction, and
each of the plurality of second electrode terminals is circular as viewed in thickness direction.

12. The semiconductor element according to claim 1, wherein each of the plurality of electrodes contains Cu.

13. The semiconductor element according to claim 1, wherein each of the plurality of electrodes includes a first layer made of Cu, a second layer made of Ni and a third layer made of Pd.

14. A semiconductor device comprising:
a semiconductor element according to claim 1; and
a sealing resin covering the semiconductor element.

15. The semiconductor device according to claim 14, further comprising a plurality of leads,
wherein the plurality of electrode terminals includes a dummy electrode terminal not bonded to any of the plurality of leads and a plurality of functional electrode terminals other than the dummy electrode terminal, and each of the plurality of functional electrode terminals is bonded to a relevant one of the plurality of leads.

16. The semiconductor device according to claim 15, further comprising a plating layer disposed between each of the plurality of functional electrode terminals and the relevant one of the leads and containing Ni.

17. The semiconductor device according to claim 14, further comprising a substrate and a plurality of wires disposed on the substrate,
wherein each of the plurality of wires is bonded to one of the plurality of electrode terminals, and
the plurality of electrode terminals include a dummy electrode terminal not bonded to any of the plurality of wires.

18. The semiconductor element according to claim 3, wherein the pillar portion includes a seed layer in contact with the relevant electrode and a plating layer disposed on the seed layer.

19. The semiconductor element according to claim 3, wherein each of the electrode terminals includes a solder portion in contact with the pillar portion.

20. The semiconductor element according to claim 4, wherein each of the electrode terminals includes a solder portion in contact with the pillar portion.
